(19) United States
(12) Patent Application Publication
(10) Pub. No.: US 2012/0070783 A1
(43) Pub. Date: Mar. 22, 2012

(54) RADIATION-SENSITIVE RESIN COMPOSITION, POLYMER, AND METHOD FOR FORMING RESIST PATTERN

(75) Inventors: Hirokazu SAKAKIBARA, Tokyo (JP); Takehiko NARUOKA, Tokyo (JP)

(73) Assignee: JSR Corporation, Tokyo (JP)

(21) Appl. No.: 13/278,202

(22) Filed: Oct. 21, 2011

Related U.S. Application Data
(63) Continuation of application No. PCT/JP2010/057022, filed on Apr. 20, 2010.

(30) Foreign Application Priority Data
Apr. 21, 2009 (JP) 2009-103449

(51) Int. Cl. G03F 7/20; G03F 7/004

(52) U.S. Cl. 430/285.1; 430/270.1; 430/325

(57) ABSTRACT

A radiation sensitive resin composition capable of forming a photoresist film which has excellent basic resist performances concerning sensitivity, LWR, development defects, etc., gives a satisfactory pattern shape, has an excellent depth of focus, is reduced in the amount of components dissolving in a liquid for immersion exposure which is in contact with the film during immersion exposure, has a large receding contact angle with the liquid for immersion exposure, and is capable of forming a microfine resist pattern with high accuracy. The radiation sensitive resin composition contains (A) a polymer that comprises a repeating unit represented by formula (1) and a repeating unit having a fluorine atom and has an acid dissociable group in the side chain, and (B) a solvent. [In the formula (1), R¹ represents a hydrogen atom, methyl, or trifluoromethyl; and Z represents a group including a structure that generates an acid upon light irradiation.]

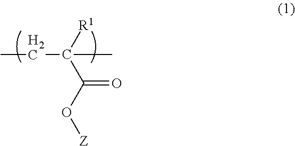

### TECHNICAL FIELD

The present invention relates to a radiation sensitive resin composition, a polymer, and a method for forming a resist pattern. More specifically, the present invention relates to a radiation sensitive resin composition which is suitably used for the formation of a resist in a liquid immersion exposure process in which a resist film is exposed to light through a liquid for a liquid immersion exposure such as water, a novel polymer used therefor, and a method for forming a resist pattern.

### BACKGROUND ART

In the field of micro-processing typified by the manufacture of an integrated circuit element, a lithography technique is recently required which makes it possible to realize more finely processing for a level to 0.10 μm or smaller. In the conventional lithography process, near ultraviolet rays such as i-rays are commonly applied as radiation, however, it is said that micro-processing for a level to subquarter micron is extremely difficult when the near ultraviolet rays are applied. Accordingly, the use of radiation having a shorter wave length than the near ultraviolet rays has been studied to enable micro-processing for a level to 0.10 μm or smaller. The short wave length radiation may be far ultraviolet rays including bright line spectrum by mercury lamp and excimer laser, X rays, electron beams, or the like. Among these, KrF excimer laser (wavelength 248 nm), and ArF excimer laser (wavelength 193 nm) are of particular interest.

A number of resists (hereinafter, referred to as “chemically-amplified resist”) utilizing the chemical amplification effect based on a component having an acid dissociable functional group and a component (hereinafter, referred to as “acid generator”) which generates an acid upon being exposed to radiation (hereinafter, referred to as “exposure”) have been proposed as a resist suitable for being exposed to such an excimer laser. A chemically-amplified resist has been proposed which comprises a resin having a t-butyl ester group of a carboxylic acid or t-butyl carbonate group of phenol and an acid generator. The t-butyl ester group or t-butyl carbonate group in the resin dissociates by an action of an acid generated upon exposure, whereby the resist has an acidic group such as a carboxyl group or a phenolic hydroxyl group. As a result, the exposed areas on the resist film become readily soluble in an alkaline developer.

Formation of finer patterns (a fine resist pattern with a line width of about 90 nm, for example) will be required for such a lithography process in the future. Reducing the wavelength of a light source of an exposure apparatus and increasing the numerical aperture (NA) of a lens are thought to be a solution for forming such a pattern with a width less than 90 nm, as described above. However, the reduction of the wavelength of a light source requires an expensive new exposure apparatus. In addition, increasing the NA of a lens involves a problem of decreasing the depth of focus even if a resolution is increased due to a trade-off relationship between the resolution and the depth of focus.

Recently, a liquid immersion exposure process (i.e., liquid immersion lithography) has been reported as a lithography technique enabling a solution to such a problem. In the liquid immersion exposure process, a liquid refractive-index medium (liquid for the liquid immersion exposure process) such as pure water or a fluorine-containing inert liquid, which has a predetermined thickness, is interposed between a lens and a resist film formed on a substrate, at least on the surface of the resist film.

In this method, when air or an inert gas such as nitrogen which has been conventionally used in an exposure optical path space is replaced with a liquid having a larger refractive index (n) such as pure water, the resolution can be increased without decreasing the depth of focus even by using a light source with the same wavelength used conventionally, to the same degree as in the case in which a light source with a shorter wavelength is used, or the case in which a higher NA lens is used. Since a resist pattern having a higher resolution and excellent depth of focus can be formed at a low cost using the lens mounted on the existing apparatuses by utilizing the liquid immersion exposure process, the liquid immersion exposure process has received a great deal of attention.

In the above-mentioned liquid immersion exposure process, however, an acid generator or the like is eluted from the resist film because the resist film is brought into direct contact with the liquid for the liquid immersion exposure process such as water during the exposure. When a large amount of the components is eluted, the lens may be damaged, a pattern having a pre-determined pattern shape may not be obtained, or a sufficient resolution may not be obtained.

Additionally, in a case in which water is used as the liquid for a liquid immersion exposure process, there are problems in that, if a receding contact angle between the resist film is low, a liquid for a liquid immersion exposure process such as water overflows and thus drips from the edge of a wafer, water may not be sufficiently removed during a high speed scanning exposure to thereby give watermarks (a trace of liquid drop) (i.e., watermark defect), or dissolution property of a film is lowered due to penetration of water into a resist film, so that an original pattern shape to be resolved may not have a sufficient resolution property locally, and as a result, development defects such as remaining dissolution defect which causes a pattern shape failure occur.

Resins described in, for example, Patent Documents 1, 2 and 4 and additives described in Patent Document 3 have been proposed as a resin for use in a liquid immersion lithographic apparatus.

However, the receding contact angle between the resist film and water is not necessarily sufficient in resists in which these resins and additives are used. A low receding contact angle tends to cause development defects such as watermarks due to the overflowing of a liquid for a liquid immersion exposure process such as water and dripping of the liquid from the edge of a wafer, or due to poor water removal during a high speed scanning exposure. Moreover, the proposed resists do not necessarily sufficiently suppress elution of an acid generator and the like to water.

### PRIOR TECHNICAL LITERATURE

### Patent Document

Patent Document 1: WO 04/068242 A
Patent Document 2: JP 2005-173474 A
Patent Document 3: JP 2006-48029 A
Patent Document 4: JP 2006-171656 A

### SUMMARY OF THE INVENTION

### Problems to be Solved by the Invention

The present invention has been achieved in view of this situation. The object of the present invention is to provide a radiation sensitive resin composition capable of forming a photoresist film which has excellent basic resist performances concerning sensitivity, LWR, development defects, etc., gives a satisfactory pattern shape, has an excellent depth of focus, is reduced in the amount of components dissolving in a liquid for immersion exposure which is in contact with the film during immersion exposure, has a large receding contact angle with the liquid for immersion exposure, and is capable of forming a microfine resist pattern with high accuracy, a novel polymer used therefor, and a method for forming a resist pattern.

### Means for Solving the Problems

Specifically, the invention provides the following.

[1] A radiation sensitive resin composition characterized by comprising,

(A) a polymer comprising a repeating unit represented by the following general formula (1) and a repeating unit having a fluorine atom (provided that the repeating unit represented by the general formula (1) is excluded), and having an acid dissociable group in the side chain, and (B) a solvent.

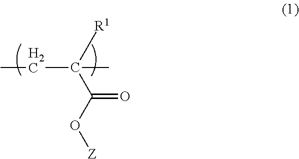

(In the general formula (1), R¹ represents a hydrogen atom, a methyl group, or a trifluoromethyl group, and Z represents a group having a structure which generates an acid when exposed to radiation.)
[2] The radiation sensitive resin composition according to [1] above, wherein the polymer (A) further comprises at least one repeating unit selected from the group consisting of a repeating unit represented by the following general formula (2), a repeating unit represented by the following general formula (3), and a repeating unit represented by the following general formula (4).

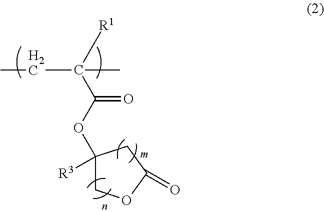

(In the general formula (2), R² represents a hydrogen atom, a methyl group, or a trifluoromethyl group, R³ represents a linear or branched alkyl group having 1 to 4 carbon atoms, m represents an integer of 1 to 3, and n represents an integer of 1 to 3.)

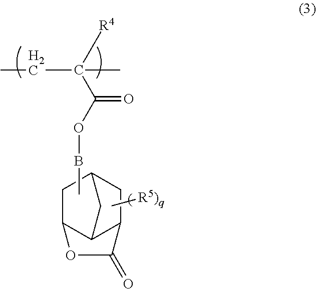

(In the general formula (3), R⁴ represents a hydrogen atom, a methyl group, or a trifluoromethyl group, R⁵ represents a hydrogen atom, a linear or branched alkyl group having 1 to 4 carbon atoms, a linear or branched fluorinated alkyl group having 1 to 4 carbon atoms, or a linear or branched alkoxyl group having 1 to 4 carbon atoms, q represents an integer of 0 to 3, B represents a single bond, an ether group, an ester group, a carbonyl group, a divalent chained hydrocarbon group having 1 to 30 carbon atoms, a divalent alicyclic hydrocarbon group having 3 to 30 carbon atoms, a divalent aromatic hydrocarbon group having 6 to 30 carbon atoms, or a divalent group obtained by combination thereof.)

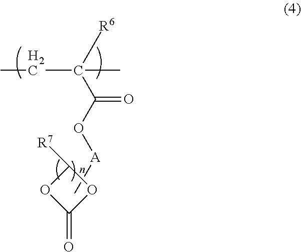

(In the general formula (4), R⁶ represents a hydrogen atom, a methyl group, or a trifluoromethyl group, R⁷ each independently represents a hydrogen atom, a chained hydrocarbon group having 1 to 5 carbon atoms, A represents a single bond, a divalent or trivalent chained hydrocarbon group having 1 to 30 carbon atoms, a divalent or trivalent alicyclic hydrocarbon group having 3 to 30 carbon atoms, or a divalent or trivalent aromatic hydrocarbon group having 6 to 30 carbon atoms; when A is trivalent, a carbon atom included in A and a carbon atom constituting the cyclic carbonic acid ester bind to each other thereby to form a ring structure, and n represents an integer of 2 to 4.)
[3] The radiation sensitive resin composition according to [1] or [2] above, wherein the polymer (A) comprises, as the repeating unit having a fluorine atom, a repeating unit which has in the side chain, a fluorine atom and an acid dissociable group, as represented by the following general formula (P-1).

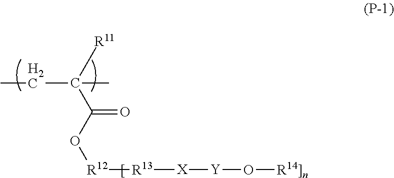

(In the general formula (P-1), n represents an integer of 1 to 3, R¹¹ represents a hydrogen atom, a methyl group, or a trifluoromethyl group, R¹² represents a single bond, or a linear, branched, or cyclic, and saturated or unsaturated hydrocarbon group having (n+1) valency with 1 to 10 carbon atoms, R¹³ represents a single bond or a divalent linear, branched or cyclic, and saturated or unsaturated hydrocarbon group having 1 to 20 carbon atoms, X represents a methylene group substituted with a fluorine atom, or a linear or branched fluoroalkylene group having 2 to 20 carbon atoms, Y represents a single bond or —CO—; when n is 1, R¹⁴ represents an acid dissociable group; when n is 2 or 3, R¹⁴ each independently represents a hydrogen atom or an acid dissociable group, and at least one R¹⁴ is an acid dissociable group.)
[4] The radiation sensitive resin composition according to [1] or [2], wherein the polymer (A) comprises, as the repeating unit having a fluorine atom, a repeating unit which has a fluorine atom in the side chain, as represented by the following general formula (P-2), and wherein the polymer (A) further comprises a repeating unit having an acid dissociable group in the side chain, as represented by the following general formula (Q-1).

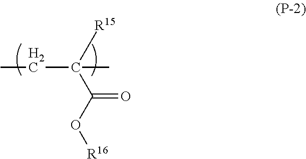

(In the general formula (P-2), R¹⁵ represents a hydrogen atom, a methyl group, or a trifluoromethyl group, R¹⁶ represents a linear or branched alkyl group having 1 to 6 carbon atoms in which at least one hydrogen atom is substituted with a fluorine atom, an alicyclic hydrocarbon group having 4 to 20 carbon atoms in which at least one hydrogen atom is substituted with a fluorine atom, or a group derived therefrom.)

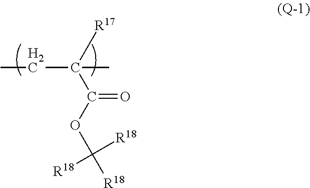

(In the general formula (Q-1), R¹⁷ represents a hydrogen atom, a methyl group, or a trifluoromethyl group, R¹⁸ each independently represents a linear or branched alkyl group having 1 to 4 carbon atoms, a monovalent alicyclic hydrocarbon group having 4 to 20 carbon atoms, or a group derived therefrom, or any two of R¹⁸ bind to each other and form, together with the carbon atom to which they are attached, a divalent alicyclic hydrocarbon group having 4 to 20 carbon atoms, or a group derived therefrom, and the remaining one R¹⁸ represents a linear or branched alkyl group having 1 to 4 carbon atoms, a monovalent alicyclic hydrocarbon group having 4 to 20 carbon atoms, or a group derived therefrom.)
[5] The radiation sensitive resin composition according to any one of [1] to [4] above, wherein the repeating unit represented by the general formula (1) is at least one repeating unit selected from the group consisting of a repeating unit represented by the following general formula (1-1) and a repeating unit represented by the following general formula (1-2).

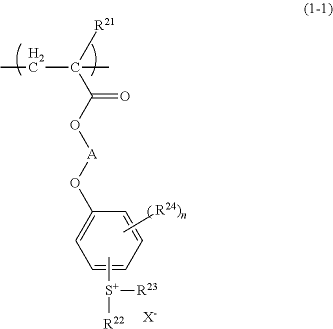

(In the general formula (1-1), R²¹ represents a hydrogen atom, a methyl group, or a trifluoromethyl group, R²², R²³ and R²⁴ each independently represent a linear or branched alkyl group having 1 to 10 carbon atoms which may have a substituent group, a linear or branched alkoxyl group having 1 to 10 carbon atoms which may have a substituent group, or an aryl group having 3 to 10 carbon atoms which may have a substituent group, n represents an integer of 0 to 3, A represents a methylene group, a linear or branched alkylene group having 2 to 10 carbon atoms, or an arylene group having 3 to 10 carbon atoms, X⁻ represents a counter ion of S⁺.)

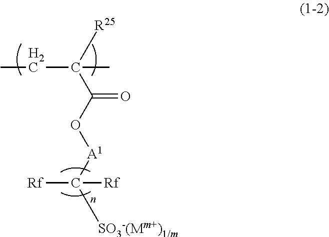

(In the general formula (1-2), R²⁵ represents a hydrogen atom, a methyl group, or a trifluoromethyl group, Rf represents a fluorine atom or a linear or branched perfluoroalkyl group having 1 to 10 carbon atoms, A¹ represents a single bond, or a divalent organic group, and M^{m+} represents a metal ion or an onium cation, m represents an integer of 1 to 3, and n represents an integer of 1 to 8.)
[6] A polymer characterized by comprising a repeating unit represented by the following general formula (1) and a repeating unit having a fluorine atom (provided that the repeating unit represented by the general formula (1) is excluded), and having an acid dissociable group in the side chain.

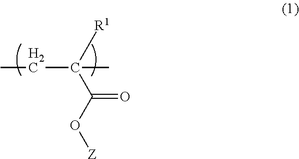

(In the general formula (1), R¹ represents a hydrogen atom, a methyl group, or a trifluoromethyl group, and Z represents a group having a structure which generates an acid when exposed to radiation.)
[7] The polymer according to [6] above, further comprising at least one repeating unit selected from the group consisting of a repeating unit represented by the following general formula (2), a repeating unit represented by the following general formula (3), and a repeating unit represented by the following general formula (4).

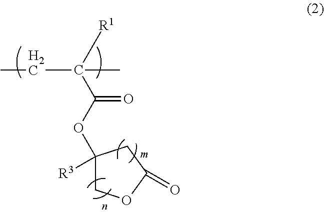

(In the general formula (2), R² represents a hydrogen atom, a methyl group, or a trifluoromethyl group, R³ represents a linear or branched alkyl group having 1 to 4 carbon atoms, m represents an integer of 1 to 3, and n represents an integer of 1 to 3.)

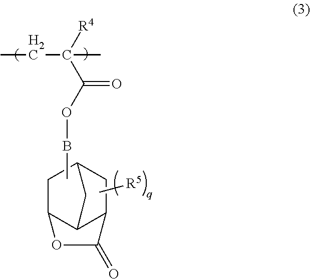

(In the general formula (3), R⁴ represents a hydrogen atom, a methyl group, or a trifluoromethyl group, R⁵ represents a hydrogen atom, a linear or branched alkyl group having 1 to 4 carbon atoms, a linear or branched fluorinated alkyl group having 1 to 4 carbon atoms, or a linear or branched alkoxyl group having 1 to 4 carbon atoms, q represents an integer of 0 to 3, B represents a single bond, an ether group, an ester group, a carbonyl group, a divalent chained hydrocarbon group having 1 to 30 carbon atoms, a divalent alicyclic hydrocarbon group having 3 to 30 carbon atoms, a divalent aromatic hydrocarbon group having 6 to 30 carbon atoms, or a divalent group obtained by combination thereof.)

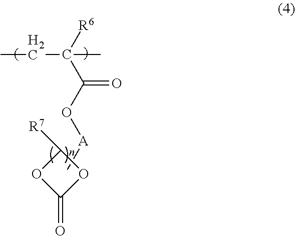

(In the general formula (4), R⁶ represents a hydrogen atom, a methyl group, or a trifluoromethyl group, R⁷ each independently represents a hydrogen atom, a chained hydrocarbon group having 1 to 5 carbon atoms, A represents a single bond, a divalent or trivalent chained hydrocarbon group having 1 to 30 carbon atoms, a divalent or trivalent alicyclic hydrocarbon group having 3 to 30 carbon atoms, or a divalent or trivalent aromatic hydrocarbon group having 6 to 30 carbon atoms; when A is trivalent, a carbon atom included in A and a carbon atom constituting the cyclic carbonic acid ester bind to each other thereby to form a ring structure, and n represents an integer of 2 to 4.)
[8] A method for forming a resist pattern, characterized by comprising:

(1) forming a photoresist film on a substrate by using the radiation sensitive resin composition according to any one of [1] to [5] above,

(2) subjecting the photoresist film to a liquid immersion exposure process, and

(3) developing the photoresist film obtained after the liquid immersion exposure process to form a resist pattern.

### Effects of the Invention

When the radiation sensitive resin composition containing a specific polymer of the present invention is used, a microfine photoresist film can be formed with high accuracy, which has excellent basic resist performances concerning sensitivity, LWR, development defects, etc., gives a satisfactory pattern shape, has an excellent depth of focus, is reduced in the amount of components dissolving in a liquid for immersion exposure which is in contact with the film during immersion exposure, has a large receding contact angle with the liquid for immersion exposure. Since the resist film is excellent in water repellency and leads to a high receding contact angle, the radiation sensitive resin composition can be suitably used for liquid immersion exposure process to obtain a resist pattern without forming a protective film on surface of the resist film. As such, it is believed that the radiation sensitive resin composition of the invention is suitable for fine lithography that will be required in the future.

### BRIEF DESCRIPTION OF THE DRAWINGS

FIG. 1 is a schematic diagram for describing the measurement of an eluted amount of a coating film formed with the radiation sensitive resin composition of the invention, in which an eight-inch silicon wafer is applied onto a silicone rubber sheet to prevent the leakage of ultra pure water.

FIG. 2 is a cross-sectional view of a coating film formed of the radiation sensitive resin composition of the invention at the time of measuring an eluted amount.

### DESCRIPTION OF EXEMPLARY EMBODIMENTS

Hereinafter, the present invention is described in detail. In the specification, “(meth)acryl” means either or both of “acryl” and “methacryl”.

The radiation sensitive resin composition of the present invention contains (A) a polymer and (B) a solvent. The resin composition is suitably used for forming a resist film in a process for forming a resist pattern, including a liquid immersion lithographic process in which radiation is emitted through a liquid (water, etc) for a liquid immersion exposure process having a refractive index larger than the refractive index of air at a wavelength of 193 nm, and being interposed between a lens and the resist film.

### <(A) Polymer>

The polymer (hereinafter, also referred to as “polymer (A)”) of the present invention has a repeating unit represented by the following general formula (1) (hereinafter, also referred to as “repeating unit (1)”) and a repeating unit having a fluorine atom (provided that, the repeating unit (1) is excluded), and an acid dissociable group in the side chain.

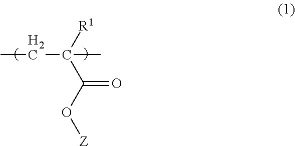

(In the general formula (1), R¹ represents a hydrogen atom, a methyl group, or a trifluoromethyl group, and Z represents a group having a structure which generates an acid when exposed to radiation.)

Z in the general formula (1) represents a group containing a structure which generates an acid upon exposure to radiation. Specific example thereof includes a group containing an onium salt, a group containing a halogen atom, a group having a diazoketone structure, a group having a sulfone structure, a group having a sulfonic acid structure, and the like.

In addition, the repeating unit (1) is preferably at least one of the repeating unit represented by the following general formula (1-1) (hereinafter, also referred to as “repeating unit (1-1)”) and the repeating unit represented by the following general formula (1-2) (hereinafter, also referred to as “repeating unit (1-2)”).

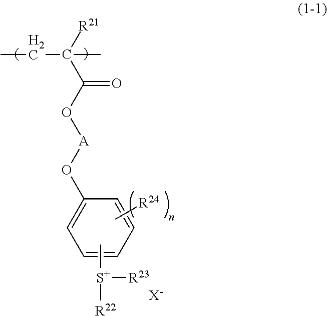

(In the general formula (1-1), R²¹ represents a hydrogen atom, a methyl group, or a trifluoromethyl group, R²², R²³ and R²⁴ each independently represent a linear or branched alkyl group having 1 to 10 carbon atoms which may have a substituent group, a linear or branched alkoxyl group having 1 to 10 carbon atoms which may have a substituent group, or an aryl group having 3 to 10 carbon atoms which may have a substituent group, n represents an integer of 0 to 3, A represents a methylene group, a linear or branched alkylene group having 2 to 10 carbon atoms, or an arylene group having 3 to 10 carbon atoms, X⁻ represents a counter ion of S⁺.)

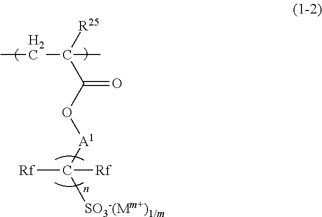

(In the general formula (1-2), R²⁵ represents a hydrogen atom, a methyl group, or a trifluoromethyl group, Rf represents a fluorine atom or a linear or branched perfluoroalkyl group having 1 to 10 carbon atoms, A¹ represents a single bond, or a divalent organic group, and M^{m+} represents a metal ion or an onium cation, m represents an integer of 1 to 3, and n represents an integer of 1 to 8.)

Examples of the linear or branched alkyl group having 1 to 10 carbon atoms which may have a substituent group as R²², R²³ and R²⁴ in the general formula (1-1) include a methyl group, an ethyl group, a n-propyl group, an i-propyl group, a n-butyl group, a 2-methylpropyl group, a 1-methylpropyl group, a t-butyl group, a pentyl group, a hexyl group, a hydroxymethyl group, a hydroxyethyl group, and a trifluoromethyl group. The alkyl group may have a substituent group such as a halogen atom, i.e. it may be a haloalkyl group.

Examples of the linear or branched alkoxyl group having 1 to 10 carbon atoms which may have a substituent group as R²², R²³ and R²⁴ include a methoxy group, an ethoxy group, a n-propoxy group, a n-propoxy group, an i-propoxy group, a n-butoxy group, a 2-methylpropoxy group, a 1-methylpropoxy group, a t-butoxy group, a n-pentyloxy group, a neopentyloxy group, a n-hexyloxy group, a n-heptyloxy group, a n-octyloxy group, a 2-ethylhexyloxy group, a n-nonyloxy group, a n-decyloxy group, and the like. The alkoxyl group may have a substituent group such as a halogen atom.

Examples of the aryl group having 3 to 10 carbon atoms which may have a substituent group as R²², R²³ and R²⁴ include a phenyl group, a naphthyl group, and the like. The aryl group may have a substituent group such as a halogen atom,

Among the monovalent organic groups described above (an alkyl group, an alkoxyl group, and an aryl group), each of R²² and R²³ in the general formula (1-1) is preferably a phenyl group or a naphthyl group from the viewpoint that the stability of the compound is excellent.

In addition, among the monovalent organic groups described above, R²⁴ in the general formula (1-1) is preferably an alkoxyl group such as a methoxy group. Further, n in the general formula (1-1) is preferably 0.

Further, A in the general formula (1-1) is a divalent organic group having 10 or less carbon atoms such as a methylene group, an alkylene group and an arylene group. When there are more than 10 carbon atoms, a sufficient etching resistance may not be obtained.

Examples of the linear or branched alkylene group having 2 to 10 carbon atoms as A include an ethylene group, a propylene group such as an ethylene group, a propylene group including a 1,3-propylene group and a 1,2-propylene group, a tetramethylene group, a pentamethylene group, a hexamethylene group, a heptamethylene group, an octamethylene group, a nonamethylene group, a decamethylene group, a 1-methyl-1,3-propylene group, a 2-methyl-1,3-propylene group, a 2-methyl-1,2-propylene group, a 1-methyl-1,4-butylene group, a 2-methyl-1,4-butylene group, and the like.

Examples of the arylene group include a phenylene group, a naphthylene group, an anthrylene group, a phenanthrylene group, and the like.

Of these, from the viewpoint that the stability of the compound is excellent, an ethylene group and a propylene group are preferable.

Moreover, examples of the arylene group having 3 to 10 carbon atoms as A include a phenylene group, a naphthylene group, and the like.

X⁻ in the general formula (1-1) represents a counter ion of S⁺, and example thereof includes a sulfonate ion, a carboxylate ion, a halogen ion, a BF⁴⁻ ion, a PF⁶⁻ ion, a tetraaryl boronium ion, and the like.

The sulfonate ion and the carboxylate ion each preferably contains an alkyl group, an aryl group, an aralkyl group, an alicyclic alkyl group, a halogen substituted alkyl group, a halogen substituted aryl group, a halogen substituted aralkyl group, an oxygen atom substituted alicyclic alkyl group, or a halogen substituted alicyclic alkyl group. Further, the halogen as a substituent group is preferably a fluorine atom.

Additionally, a chloride ion and a bromide ion are preferable as the halogen ion.

Further, as the tetraaryl boronium ion, BPh⁴⁻ and B[C₆H₄(CF₃)₂]⁴⁻ ions are preferable.

The following formula (1-1-1) is a preferable example for the monomer which provides the repeating unit (1-1).

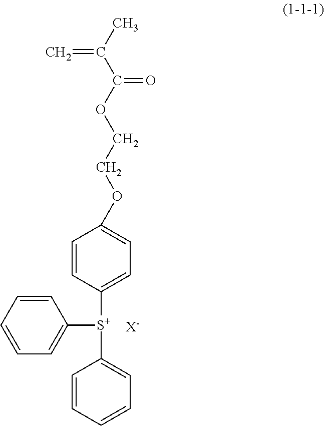

The following formulae (1a-1) to (1a-26) are specific examples for X⁻ in the formula (1-1-1).

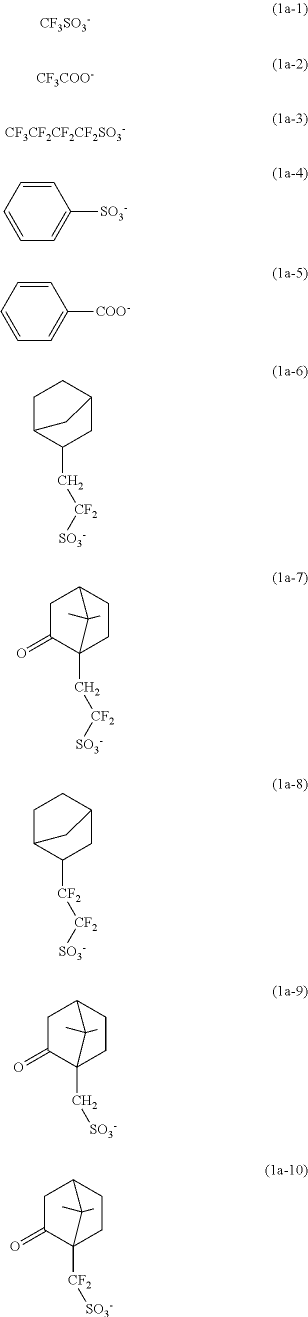

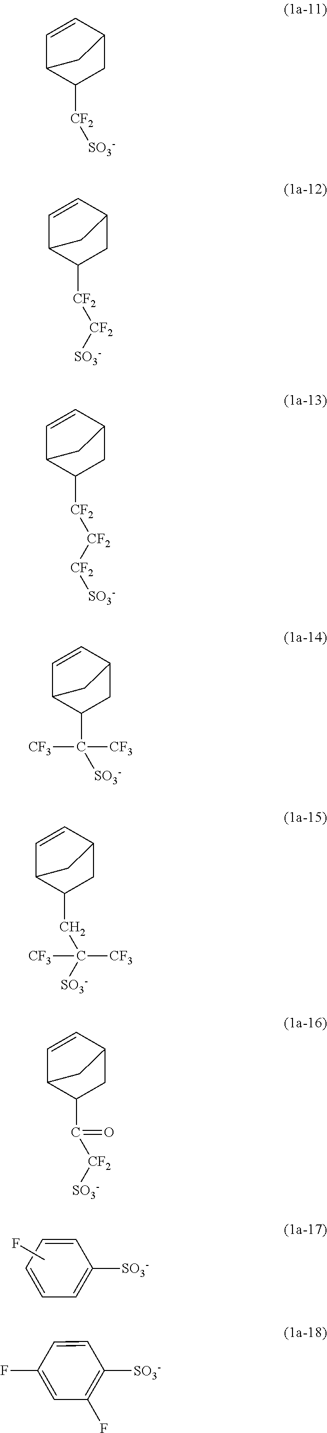

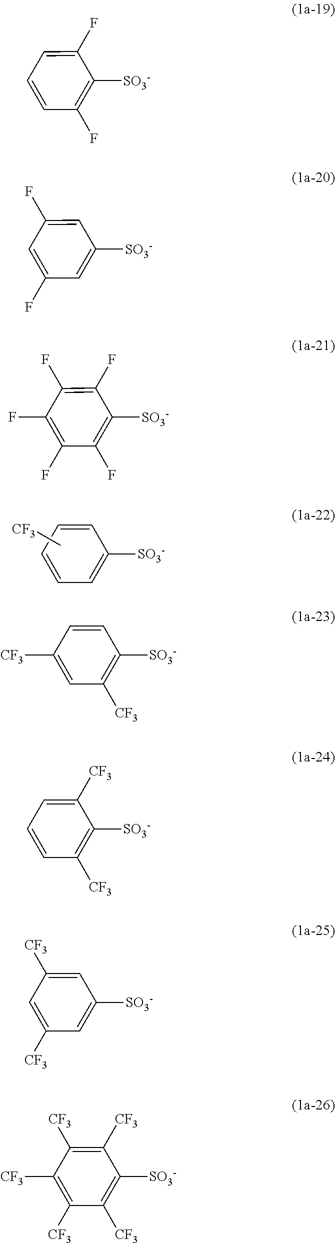

Examples of the linear or branched perfluoroalkyl group having 1 to 10 carbon atoms as Rf in the general formula (1-2) include a linear perfluoroalkyl group such as a trifluoromethyl group, a pentafluoroethyl group, a heptafluoropropyl group, a nonafluorobutyl group, a undecafluoropentyl group, a tridecafluorohexyl group, a pentadecafluoroheptyl group, a heptadecafluorooctyl group, a nonadecafluorononyl group, and a heneicosadecyl group; a branched perfluoroalkyl group such as a (1-trifluoromethyl)tetrafluoroethyl group, a (1-trifluoromethyl)hexafluoropropyl group, and a 1,1-bistrifluoromethyl-2,2,2-trifluoroethyl group; and the like.

From the viewpoint of obtaining an excellent resolution, Rf is preferably a fluorine atom or a trifluoromethyl group.

Further, two Rf in the general formula (1-2) may be the same or different from each other.

Additionally, n in the general formula (1-2) is an integer of 1 to 8, and preferably 1 or 2.

Examples of the divalent organic group as A¹ in the general formula (1-2) include a divalent hydrocarbon group, a —CO— group, a —SO₂— group, and the like.

The divalent hydrocarbon group may be a chained or cyclic hydrocarbon group and example thereof includes a saturated chained hydrocarbon group such as a methylene group, an ethylene group, a propylene group including a 1,3-propylene group and a 1,2-propylene group, a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, an icosylene group, a 1-methyl-1,3-propylene group, a 2-methyl-1,3-propylene group, a 2-methyl-1,2-propylene group, a 1-methyl-1,4-butylene group, a 2-methyl-1,4-butylene group, a methylidene group, an ethylidene group, a propylidene group, and a 2-propylidene group; a monocyclic hydrocarbon ring group such as a cycloalkylene group having 3 to 10 carbon atoms including a cyclobutylene group such as a 1,3-cyclobutylene group, a cyclopenthylene group such as a 1,3-cyclopentylene group, a cyclohexylene group such as a 1,4-cyclohexylene group, a cyclooctylene group such as a 1,5-cyclooetylene group, and the like; a bi- to tetra-cyclic crosslinked hydrocarbon group having 4 to 30 carbon atoms such as a norbornylene group such as a 1,4-norbornylene group and a 2,5-norbornylene group, an adamantylene group such as a 1,5-adamantylene group and a 2,6-adamantylene group; and the like.

In particular, A¹ is preferably a single bond, a —CO— group, a methylene group, an ethylene group, or a norbornylene group.

Examples of the metal ion as M^{m+} in the general formula (1-2) include an alkali metal ion such as sodium ion, potassium ion, and lithium ion; an alkaline earth metal ion such as magnesium ion and calcium ion; an iron ion, an aluminum ion, and the like. Of these, from the viewpoint of easy ion exchange with a sulfonate salt, a sodium ion, a potassium ion, and a lithium ion are preferable.

Examples of the onium cation as M^{m+} include an onium cation such as a sulfonium cation, an iodonium cation, a phosphonium cation, a diazonium cation, an ammonium cation, and a pyridinium ion. Of these, a sulfonium cation represented by the following general formula (2a) and an iodonium cation represented by the following general formula (2b) are preferable.

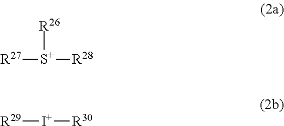

(In the general formula (2a), R²⁶, R²⁷ and R²⁸ each independently represent a substituted or unsubstituted alkyl group having 1 to 10 carbon atoms, or a substituted or unsubstituted aryl group having 4 to 18 carbon atoms, or any two or more of R²⁶, R²⁷ and R²⁸ bind to each other to form a ring together with the sulfur atom in the formula.)
(In the general formula (2b), R²⁹ and R³⁰ each independently represent a substituted or unsubstituted alkyl group having 1 to 10 carbon atoms, or a substituted or unsubstituted aryl group having 4 to 18 carbon atoms, or R²⁹ and R³⁰ bind to each other to form a ring together with the iodine atom in the formula.)

The unsubstituted alkyl group having 1 to 10 carbon atoms as R²⁶ to R³⁰ in the general formulae (2a) and (2b) may be a linear or branched alkyl group. Example thereof includes a methyl group, an ethyl group, a n-propyl group, an i-propyl group, a n-butyl group, a 1-methylpropyl group, a 2-methylpropyl group, a t-butyl group, a n-pentyl group, an i-pentyl group, a 1,1-dimethylpropyl group, a 1-methylbutyl group, a n-hexyl group, an i-hexyl group, a 1,1-dimethylbutyl group, a n-heptyl group, a n-octyl group, an i-octyl group, a 2-ethylhexyl group, a n-nonyl group, a n-decyl group, 10 and the like,

In addition, the linear or branched alkyl group having 1 to 10 carbon atoms as R²⁶ to R³⁰ may be the unsubstituted alkyl group described above in which at least one hydrogen atom is substituted with an aryl group, a linear, a branched, or a cyclic alkenyl group, a halogen atom, or a group containing a heteroatom such as an oxygen atom, a nitrogen atom, a sulfur atom, a phosphorus atom, and a silicon atom. Specific example thereof includes a benzyl group, a methoxymethyl group, a methylthiomethyl group, an ethoxymethyl group, an ethylthiomethyl group, a phenoxymethyl group, a methoxycarbonylmethyl group, an ethoxycarbonylmethyl group, an acetylmethyl group, a fluoromethyl group, a trifluoromethyl group, a chloromethyl group, a trichloromethyl group, 2-fluoromethyl group, a (trifluoroacetyl)methyl group, a (trichloroacetyl)methyl group, a (pentafluorobenzoyl)methyl group, an aminomethyl group, a (cyclohexylamino)methyl group, a (trimethylsilyl)methyl group, a 2-phenylethyl group, a 2-aminoethyl group, a 3-phenylpropyl group, and the like.

Examples of the unsubstituted aryl group having 4 to 18 carbon atoms as R²⁶ to R³⁰ in the general formulae (2a) and (2b) include a phenyl group, a 1-naphthyl group, a 2-naphthyl group, a 1-anthryl group, a 1-phenanthryl group, a furanyl group, a thiophenyl group, and the like.

Additionally, the substituted aryl group having 4 to 18 carbon atoms as R²⁶ to R³⁰ may be the unsubstituted aryl group described above in which at least one hydrogen atom is substituted with a linear, a branched, or a cyclic alkyl group, a halogen atom, or a group containing a heteroatom such as an oxygen atom, a nitrogen atom, a sulfur atom, a phosphorus atom, and a silicon atom. Specific example thereof includes an o-tolyl group, a m-tolyl group, a p-tolyl group, a 4-hydroxyphenyl group, a 4-methoxyphenyl group, a mesityl group, an o-cumenyl group, a 2,3-xylyl group, a 2,4-xylyl group, a 2,5-xylyl group, a 2,6-xylyl group, a 3,4-xylyl group, a 3,5-xylyl group, a 4-fluorophenyl group, a 4-trifluoromethylphenyl group, a 4-chlorophenyl group, a 4-bromophenyl group, a 4-iodophenyl group, and the like.

Further, the substituted aryl group having 4 to 18 carbon atoms as R²⁶ to R³⁰ may be the unsubstituted aryl group described above in which at least one hydrogen atom is substituted with a group having two or more heteroatoms. The group having two or more heteroatoms is not specifically limited, but it is preferably at least one of —OSO₂-Rx and —SO₂-Rx (Rx each independently represents an alkyl group, a cycloalkyl group, an alkoxyl group, or an aryl group which may have a substituent group). Examples of the substituent group for Rx include a halogen atom.

Specific examples of the group having two or more heteroatoms include a group having the structure represented by the following formula (h1) to (h8). Of these, the groups represented by the formulae (h1) and (h2) are preferable.

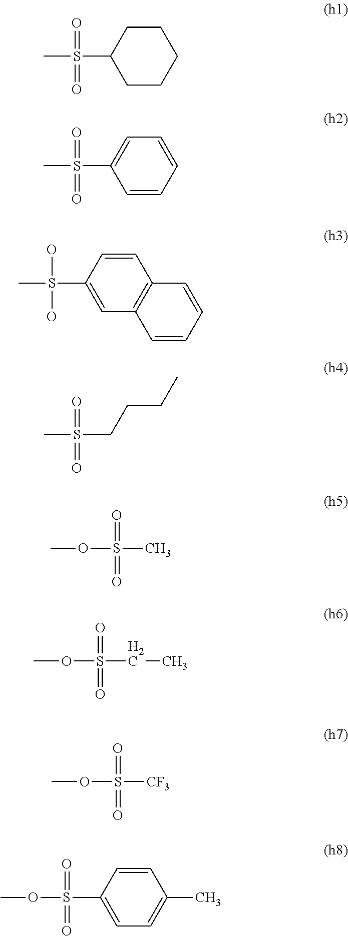

Examples of the ring which is formed by binding of two or more of R²⁶, R²⁷ and R²⁸ together with the sulfur atom in the general formula (2a) include 5- to 7-membered ring structures, and the like.

Further, examples of the ring which is formed by binding of R²⁹ and R³⁰ together with the iodine atom in the general formula (2b) include 5- to 7-membered ring structures, and the like.

Preferable examples (2a-1) to (2a-70) of the sulfonium cation represented by the general formula (2a) and examples (2b-1) to (2b-39) of the iodonium cation represented by the general formula (2b) are given below.

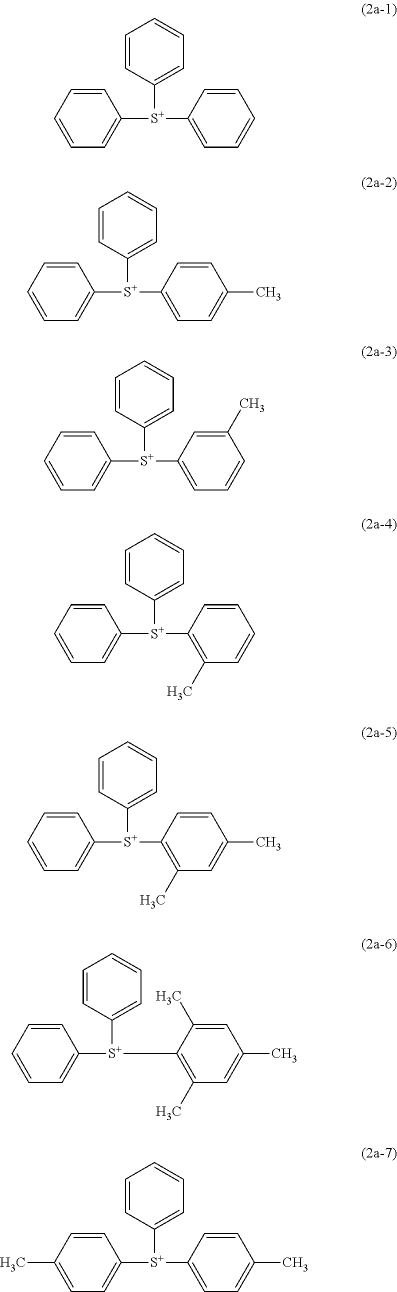

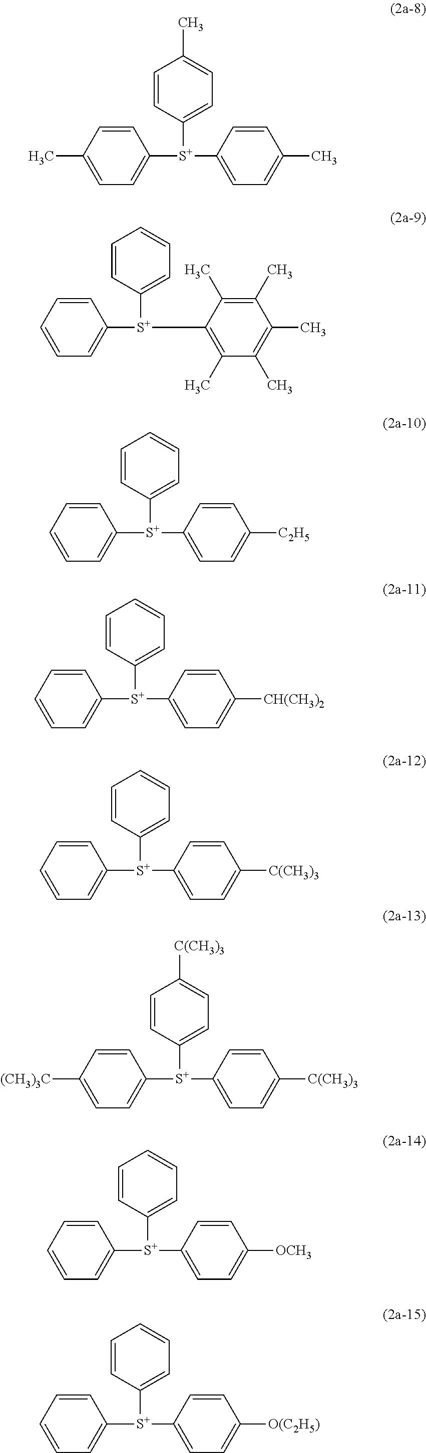

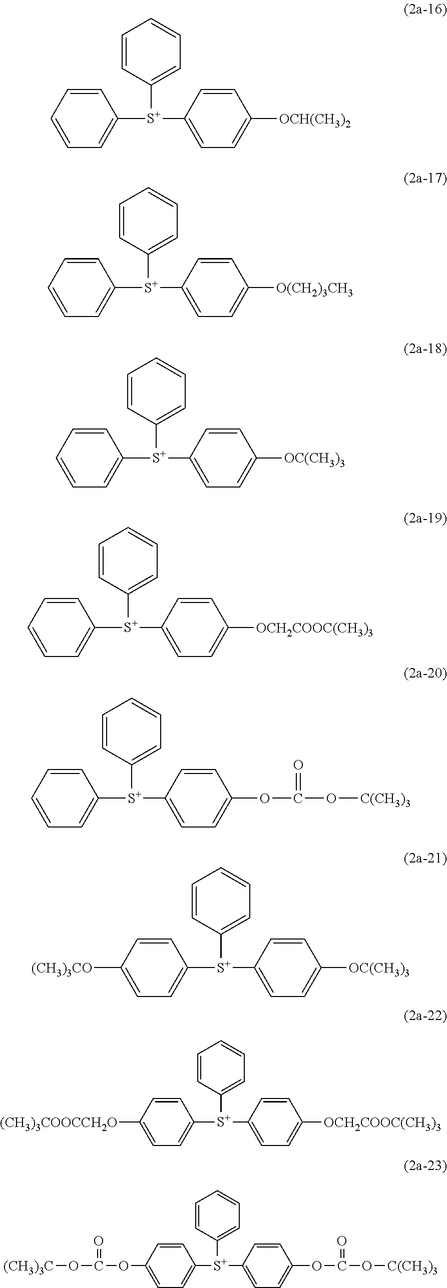

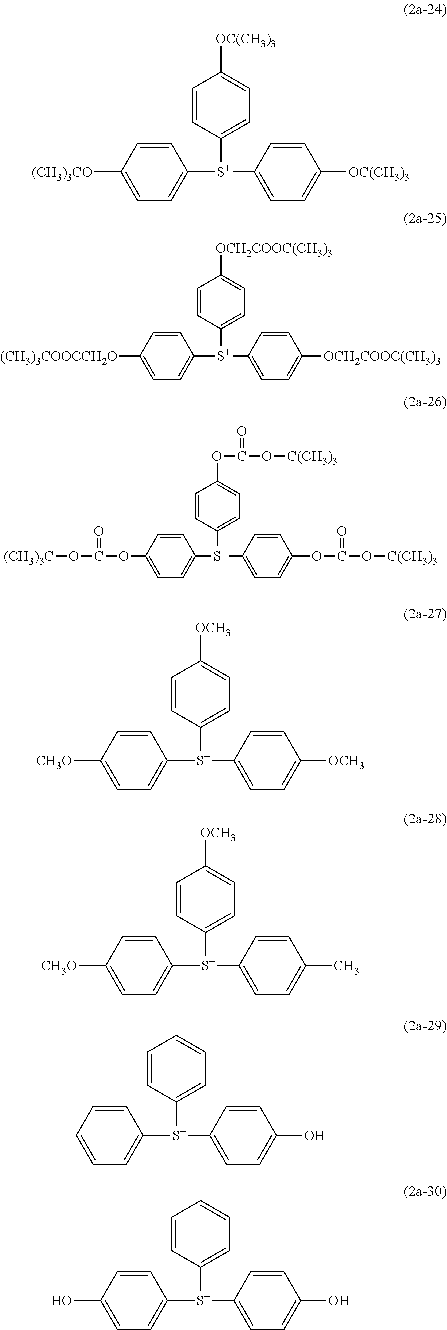

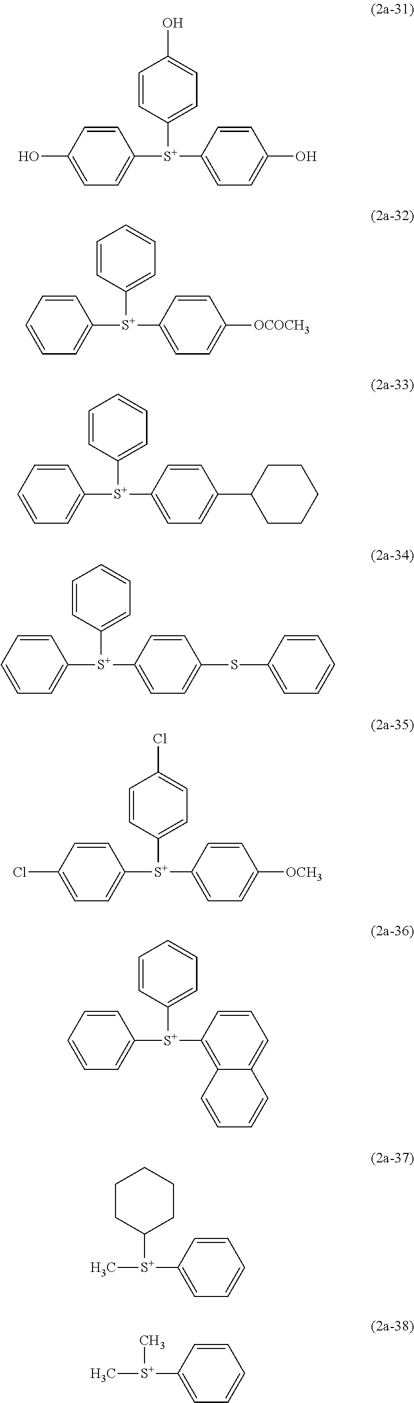

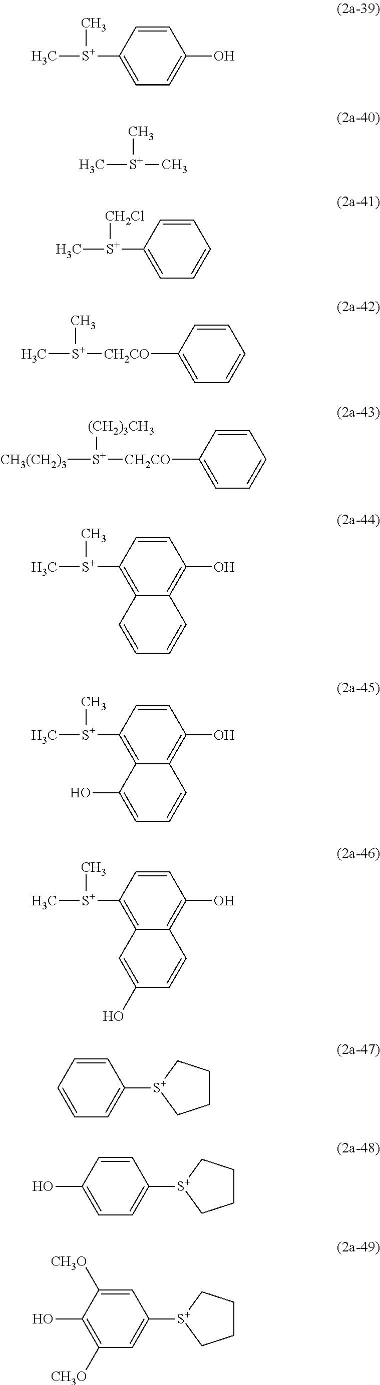

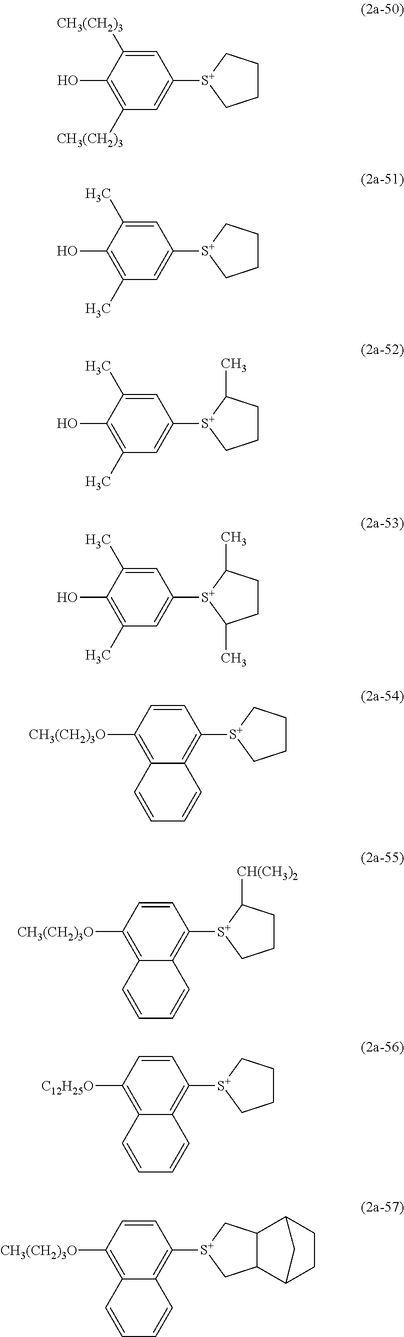

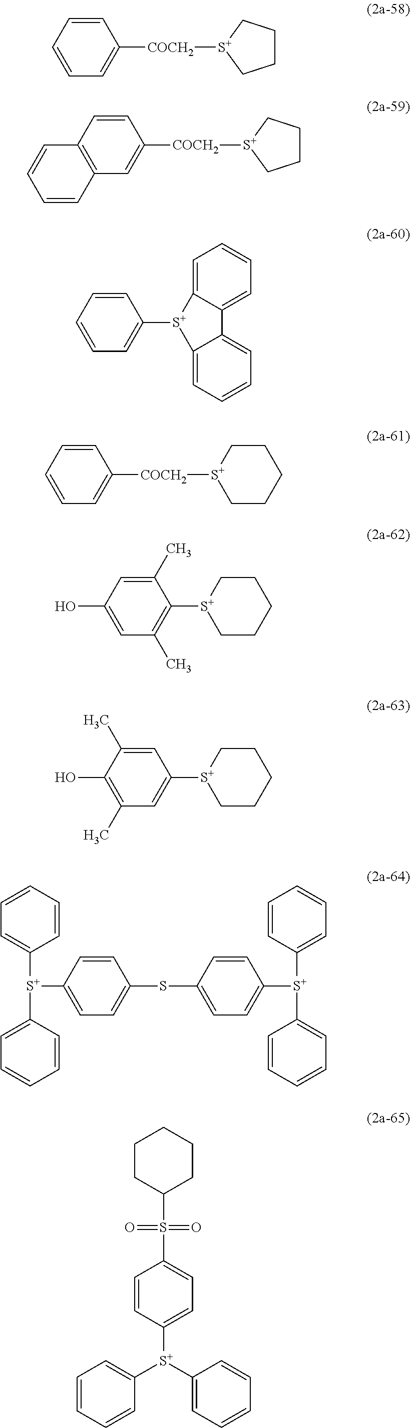

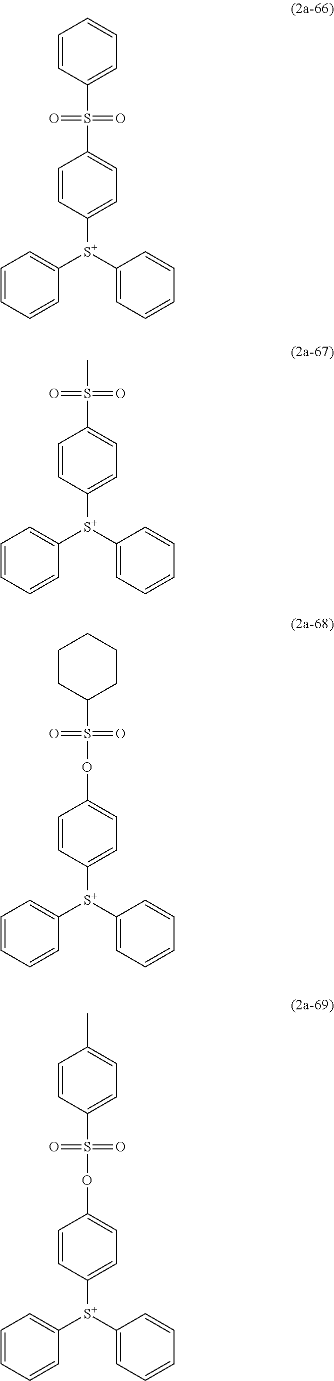

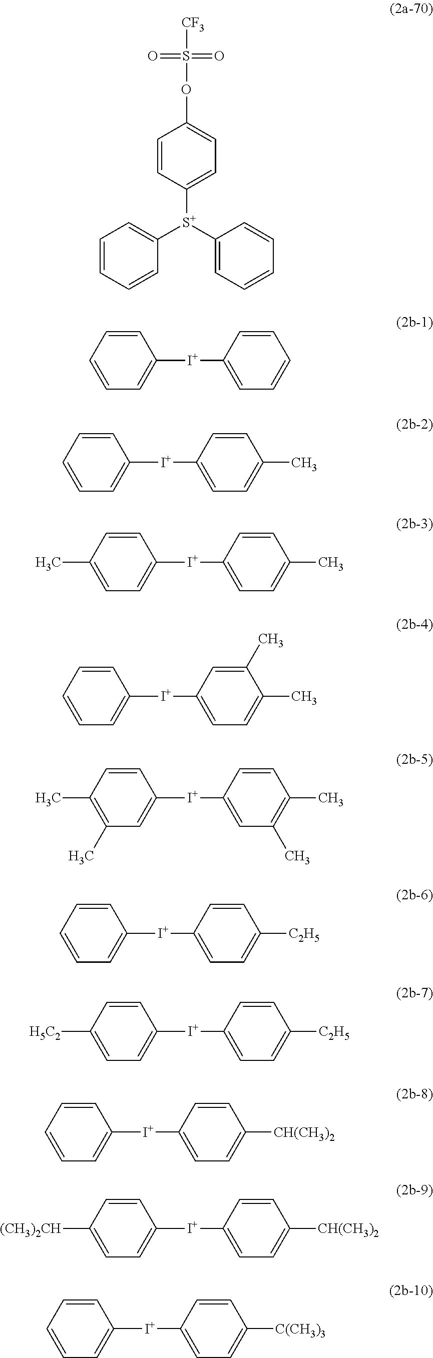

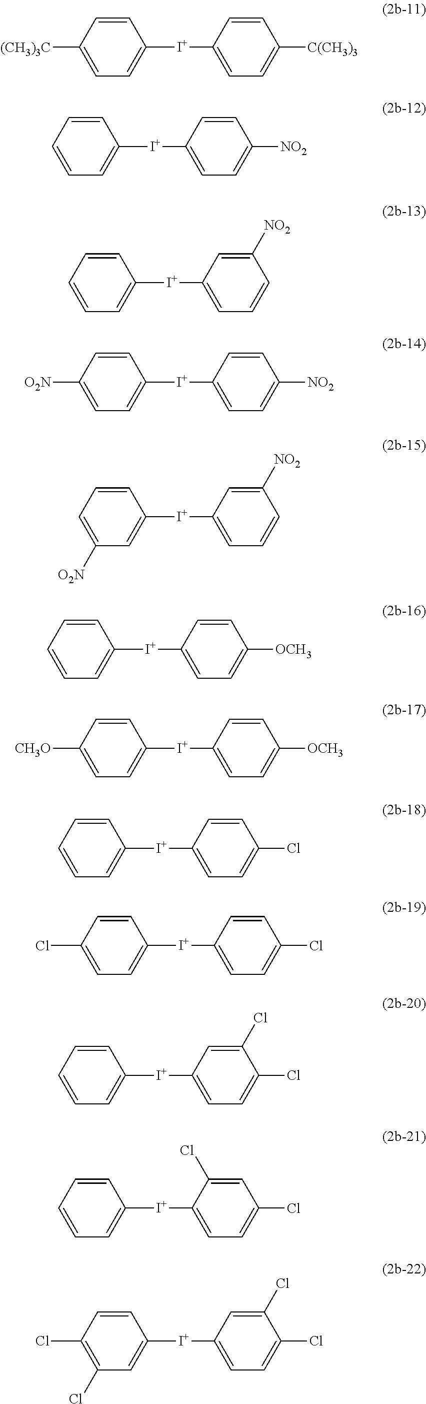

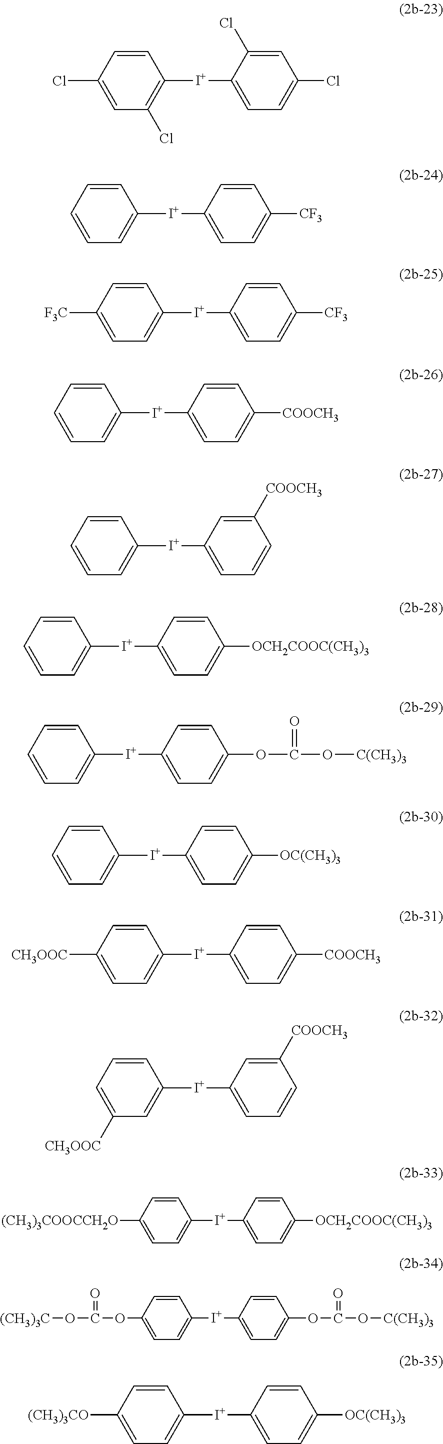

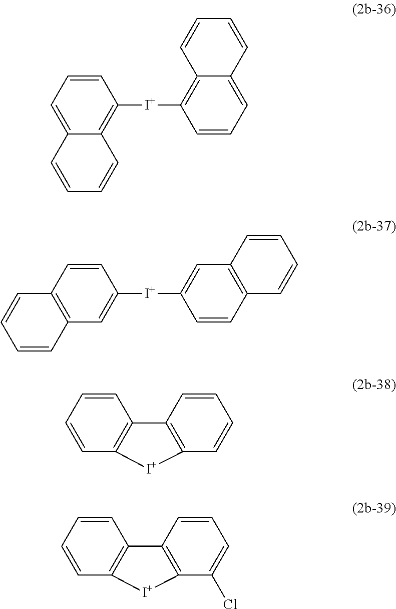

The preferable examples of the monomer for providing the repeating unit (1-2) are compounds represented by the following formulae (1-2-1), (1-2-2), and (1-2-3).

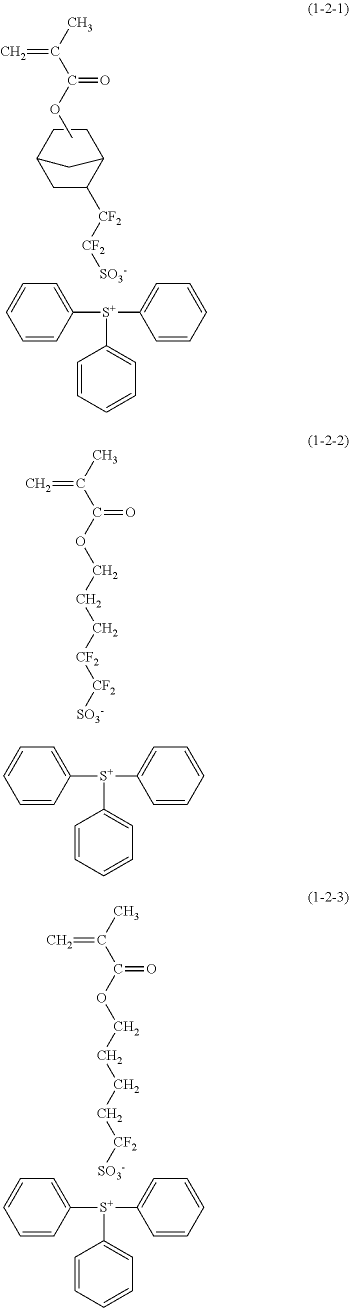

The polymer (A) of the present invention may have only one kind of the repeating unit (1) or two or more kinds thereof.

Examples of the repeating unit having a fluorine atom (hereinafter, also referred to as “fluorine atom-containing repeating unit”) contained in the polymer (A) include a repeating unit having a fluorine atom and an acid dissociable group in the side chain (hereinafter, also referred to as “repeating unit (P1)”) and a repeating unit having a fluorine atom in the side chain but no acid dissociable group (hereinafter, also referred to as “repeating unit (P2)”).

The repeating unit (P1) is not specifically limited so long as it has a fluorine atom and an acid dissociable group in the side chain, i.e. it has a side chain having both a fluorine atom and an acid dissociable group. It is preferably a repeating unit represented by the following general formula (P-1).

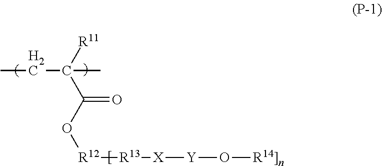

(In the general formula (P-1), n represents an integer of 1 to 3, R¹¹ represents a hydrogen atom, a methyl group, or a trifluoromethyl group, R¹² represents a single bond, or a linear, branched, or cyclic, and saturated or unsaturated hydrocarbon group having (n+1) valency with 1 to 10 carbon atoms, R¹³ represents a single bond or a divalent linear, branched or cyclic, and saturated or unsaturated hydrocarbon group having 1 to 20 carbon atoms, X represents a methylene group substituted with a fluorine atom, or a linear or branched fluoroalkylene group having 2 to 20 carbon atoms, Y represents a single bond or —CO—; when n is 1, R¹⁴ represents an acid dissociable group; when n is 2 or 3, R¹⁴ each independently represents a hydrogen atom or an acid dissociable group, and at least one R¹⁴ is an acid dissociable group.)

Examples of the divalent, linear or branched, and saturated or unsaturated hydrocarbon group having 1 to 10 carbon atoms (for a case in which n=1) as R¹² in the general formula (P-1) include a divalent hydrocarbon group derived from a linear or branched alkyl group having 1 to 10 carbon atoms such as a methyl group, an ethyl group, a n-propyl group, an i-propyl group, a n-butyl group, a 2-methylpropyl group, a 1-methylpropyl group, a t-butyl group, a pentyl group, an isopentyl group, a neopentyl group, a hexyl group, a heptyl group, an octyl group, a nonyl group, and a decyl group; and the like.

Additionally, examples of the divalent, cyclic, and saturated or unsaturated hydrocarbon group (for a case in which n=1) as R¹² in the general formula (P-1) include a group derived from an alicyclic hydrocarbon having 3 to 10 carbon atoms and an aromatic hydrocarbon.

Examples of the alicyclic hydrocarbon include a cycloalkane such as a cyclobutane, a cyclopentane, a bicyclo[2.2.1]heptane, a bicyclo[2.2.2]octane, a tricyclo[5.2.1.0^{2,6}]decane, and a tricyclo[3.3.1.1^{3,7}]decane; and the like.

Examples of the aromatic hydrocarbon include benzene, naphthalene, and the like.

The hydrocarbon group represented by R¹² may be a group obtained by substituting at least one hydrogen atom of the unsubstituted hydrocarbon group with at least one of a linear, branched, or cyclic alkyl group having 1 to 4 carbon atoms, such as a methyl group, an ethyl group, a n-propyl group, an i-propyl group, a n-butyl group, a 2-methylpropyl group, a 1-methylpropyl group, or a t-butyl group, a hydroxyl group, a cyano group, a hydroxyalkyl group having 1 to 10 carbon atoms, a carboxyl group, an oxygen atom, and the like.

Examples of the trivalent (n=2) hydrocarbon group represented by R¹² include groups obtained by elimination of one hydrogen atom from the above divalent hydrocarbon group. Examples of the tetravalent (n=3) hydrocarbon group represented by R¹² include groups obtained by elimination of two hydrogen atoms from the above divalent hydrocarbon group.

Examples of the divalent, linear or branched, and saturated or unsaturated hydrocarbon group having 1 to 10 carbon atoms as R¹³ in the general formula (P-1) include a divalent hydrocarbon group derived from a linear or branched alkyl group having 1 to 10 carbon atoms such as a methyl group, an ethyl group, a n-propyl group, an i-propyl group, a n-butyl group, a 2-methylpropyl group, a 1-methylpropyl group, a t-butyl group, a pentyl group, an isopentyl group, a neopentyl group, a hexyl group, a heptyl group, an octyl group, a nonyl group, and a decyl group; and the like.

Additionally, examples of the divalent, cyclic, and saturated or unsaturated hydrocarbon group as R¹³ in the general formula (P-1) include a group derived from an alicyclic hydrocarbon having 3 to 20 carbon atoms and an aromatic hydrocarbon.

Examples of the alicyclic hydrocarbon include a cycloalkane such as a cyclobutane, a cyclopentane, a bicyclo[2.2.1]heptane, a bicyclo[2.2.2]octane, a tricyclo[5.2.1.0^{2,6}]decane, a tricyclo[3.3.1.1^{3,7}]decane, and a tetracyclo[6.2.1.1^{3,6}.0^{2,7}]dodecane; and the like.

Examples of the aromatic hydrocarbon include benzene, naphthalene, and the like.

The hydrocarbon group represented by R¹³ may be a group obtained by substituting at least one hydrogen atom of the unsubstituted hydrocarbon group with at least one of a linear, branched, or cyclic alkyl group having 1 to 4 carbon atoms, such as a methyl group, an ethyl group, a n-propyl group, an i-propyl group, a n-butyl group, a 2-methylpropyl group, a 1-methylpropyl group, or a t-butyl group, a hydroxyl group, a cyano group, a hydroxyalkyl group having 1 to 10 carbon atoms, a carboxyl group, an oxygen atom, and the like.

Additionally, when n in the general formula (P-1) is 2 or 3, all R¹³ may be the same group, or part or all of them may be different from each other.

The acid-dissociable group represented by R¹⁴ in the general formula (P-1) refers to a group that substitutes a hydrogen atom of an acidic functional group such as a hydroxyl group, a carboxyl group, or a sulfonic acid group, and dissociates in the presence of an acid.

Examples of the acid-dissociable group include a t-butoxycarbonyl group, a tetrahydropyranyl group, a tetrahydrofuranyl group, a (thiotetrahydropyranylsulfanyl)methyl group, a (thiotetrahydrofuranylsulfanyl)methyl group, an alkoxy-substituted methyl group, an alkylsulfanyl-substituted methyl group, and the like.

Examples of the alkoxyl group (substituent) for the alkoxy-substituted methyl group include an alkoxyl group having 1 to 4 carbon atoms. Examples of the alkyl group (substituent) for the alkylsulfanyl-substituted methyl group include an alkyl group having 1 to 4 carbon atoms.

Further, examples of the acid-dissociable group include a group shown by the general formula “—C(R)₃” (wherein R individually represent a linear or branched alkyl group having 1 to 4 carbon atoms, a monovalent alicyclic hydrocarbon group having 4 to 20 carbon atoms, or a group derived therefrom, or two of R bond to form a divalent alicyclic hydrocarbon group having 4 to 20 carbon atoms, or a group derived therefrom, together with a carbon atom bonded thereto, and the remaining R represents a linear or branched alkyl group having 1 to 4 carbon atoms, a monovalent alicyclic hydrocarbon group having 4 to 20 carbon atoms, or a group derived therefrom).

Examples of the linear or branched alkyl group having 1 to 4 carbon atoms represented by R in the acid-dissociable group shown by the general formula “—C(R)₃” include a methyl group, an ethyl group, a n-propyl group, an i-propyl group, a n-butyl group, a 2-methylpropyl group, a 1-methylpropyl group, a t-butyl group, and the like.

Examples of the monovalent alicyclic hydrocarbon group having 4 to 20 carbon atoms represented by R include a group that includes an alicyclic ring derived from a cycloalkane (e.g., norbornane, tricyclodecane, tetracyclododecane, adamantane, cyclobutane, cyclopentane, cyclohexane, cycloheptane, or cyclooctane), and the like.

Examples of a group derived from the alicyclic hydrocarbon group include a group obtained by substituting the monovalent alicyclic hydrocarbon group with at least one linear, branched, or cyclic alkyl group having 1 to 4 carbon atoms, such as a methyl group, an ethyl group, a n-propyl group, an i-propyl group, a n-butyl group, a 2-methylpropyl group, a 1-methylpropyl group, or a t-butyl group, and the like.

Among these, an alicyclic hydrocarbon group that includes an alicyclic ring derived from norbornane, tricyclodecane, tetracyclododecane, adamantane, cyclopentane, or cyclohexane, a group obtained by substituting the alicyclic hydrocarbon group with the above alkyl group, and the like are preferable.

Examples of the divalent alicyclic hydrocarbon group having 4 to 20 carbon atoms that is formed by two of R together with the carbon atom that is bonded thereto (i.e., the carbon atom bonded to the oxygen atom) include a cyclobutylene group, a cyclopentylene group, a cyclohexylene group, a cyclooctylene group, and the like.

Examples of a group derived from the divalent alicyclic hydrocarbon group formed by two of R include a group obtained by substituting the divalent alicyclic hydrocarbon group with at least one linear, branched, or cyclic alkyl group having 1 to 4 carbon atoms, such as a methyl group, an ethyl group, a n-propyl group, an i-propyl group, a n-butyl group, a 2-methylpropyl group, a 1-methylpropyl group, or a t-butyl group, and the like.

Among these, a cyclopentylene group, a cyclohexylene group, a group obtained by substituting the divalent alicyclic hydrocarbon group with any of the above alkyl groups, and the like are preferable.

Examples of a preferable acid-dissociable group shown by the general formula “—C(R)₃” include a t-butyl group, a 1-n-(1-ethyl-1-methyl)propyl group, a 1-n-(1,1-dimethyl)propyl group, a 1-n-(1,1-dimethyl)butyl group, a 1-n-(1,1-dimethyl)pentyl group, 1-(1,1-diethyl)propyl group, a 1-n-(1,1-diethyl)butyl group, a 1-n-(1,1-diethyl)pentyl group, a 1-(1-methyl)cyclopentyl group, a 1-(1-ethyl)cyclopentyl group, a 1-(1-n-propyl)cyclopentyl group, a 1-(1-1-propyl)cyclopentyl group, a 1-(1-methyl)cyclohexyl group, a 1-(1-ethyl)cyclohexyl group, a 1-(1-n-propyl)cyclohexyl group, a 1-(1-1-propyl)cyclohexyl group, a 1-{1-methyl-1-(2-norbornyl)}ethyl group, a 1-{1-methyl-1-(2-tetracyclodecanyl)}ethyl group, a 1-{1-methyl-1-(1-adamantyl)}ethyl group, a 2-(2-methyl)norbornyl group, a 2-(2-ethyl)norbornyl group, a 2-(2-n-propyl)norbornyl group, a 2-(2-i-propyl)norbornyl group, a 2-(2-methyl)tetracyclodecanyl group, a 2-(2-ethyl)tetracyclodecanyl group, a 2-(2-n-propyl)tetracyclodecanyl group, a 2-(2-i-propyl)tetracyclodecanyl group, a 1-(1-methyl)adamantyl group, a 1-(1-ethyl)adamantyl group, a 1-(1-n-propyl)adamantyl group, a 1-(1-i-propyl)adamantyl group, groups obtained by substituting these groups with at least one linear, branched, or cyclic alkyl group having 1 to 4 carbon atoms, such as a methyl group, an ethyl group, a n-propyl group, an i-propyl group, a n-butyl group, a 2-methylpropyl group, a 1-methylpropyl group, or a t-butyl group, and the like.

Among these, the group shown by the general formula “—C(R)₃”, a t-butoxycarbonyl group, an alkoxy-substituted methyl group, and the like are preferable. In particular, a t-butoxycarbonyl group or an alkoxy-substituted methyl group is preferable when protecting a hydroxyl group, and the group shown by the general formula “—C(R)₃” is preferable when protecting a carboxyl group.

Examples of the methylene group substituted with a fluorine atom or the linear or branched fluoroalkylene group having 2 to 20 carbon atoms represented by X in the general formula (P-1) include structures shown by the following formulas (X-1) to (X-8), and the like.

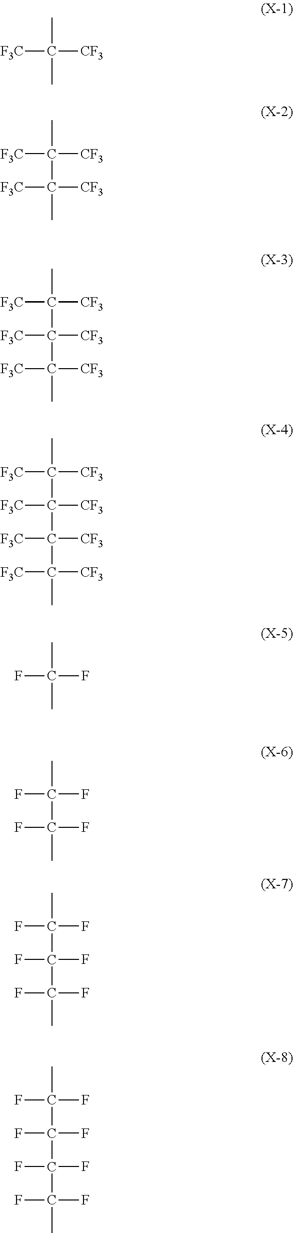

Examples of the repeating unit shown by the general formula (P-1) include a repeating unit shown by the following general formula (P-1-1).

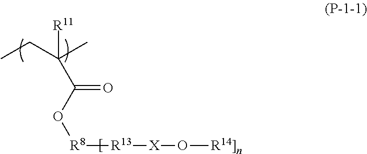

(In the general formula (P-1-1), n is an integer of 1 to 3. R¹¹ represents a hydrogen atom, a methyl group, or a trifluoromethyl group, R¹³ represents a single bond or a divalent linear, branched or cyclic, and saturated or unsaturated hydrocarbon group having 1 to 20 carbon atoms, X represents a methylene group substituted with a fluorine atom, or a linear or branched fluoroalkylene group having 2 to 20 carbon atoms; when n is 1, R¹⁴ represents an acid dissociable group; when n is 2 or 3, R¹⁴ each independently represents a hydrogen atom or an acid dissociable group, and at least one R¹⁴ is an acid dissociable group; R⁸ represents a (n+1) valency, linear, branched, or cyclic, and saturated or unsaturated hydrocarbon group having with 3 to 10 carbon atoms.)

The description given above in connection with R¹³, R¹⁴ and X in the general formula (P-1-1) may be applied to the groups represented by R¹³, R¹⁴ and X in the general formula (P-1).

Examples of the divalent, linear or branched, and saturated or unsaturated hydrocarbon group having 3 to 10 carbon atoms (for a case in which n=1) as R⁸ in the general formula (P-1) include a divalent hydrocarbon group derived from a linear or branched alkyl group having 1 to 10 carbon atoms such as a n-propyl group, an i-propyl group, a n-butyl group, a 2-methylpropyl group, a 1-methylpropyl group, a t-butyl group, a pentyl group, an isopentyl group, a neopentyl group, a hexyl group, a heptyl group, an octyl group, a nonyl group, and a decyl group; and the like.

Additionally, examples of the divalent, cyclic, and saturated or unsaturated hydrocarbon group (for a case in which n=1) as R⁸ in the general formula (P-1-1) include a group derived from an alicyclic hydrocarbon having 3 to 10 carbon atoms and an aromatic hydrocarbon.

Examples of the alicyclic hydrocarbon include a cycloalkane such as a cyclobutane, a cyclopentane, a bicyclo[2.2.1]heptane, a bicyclo[2.2.2]octane, a tricyclo[5.2.1.0^{2,6}]decane, and a tricyclo[3.3.1.1^{3,7}]decane; and the like.

Examples of the aromatic hydrocarbon include benzene, naphthalene, and the like.

The hydrocarbon group represented by R⁸ may be a group obtained by substituting at least one hydrogen atom of the unsubstituted hydrocarbon group with at least one of a linear, branched, or cyclic alkyl group having 1 to 4 carbon atoms, such as a methyl group, an ethyl group, a n-propyl group, an i-propyl group, a n-butyl group, a 2-methylpropyl group, a 1-methylpropyl group, or a t-butyl group, a hydroxyl group, a cyano group, a hydroxyalkyl group having 1 to 10 carbon atoms, a carboxyl group, an oxygen atom, and the like.

Examples of the trivalent (n=2) hydrocarbon group represented by R⁸ include groups obtained by elimination of one hydrogen atom from the above divalent hydrocarbon group. Examples of the tetravalent (n=3) hydrocarbon group represented by R¹² include groups obtained by elimination of two hydrogen atoms from the above divalent hydrocarbon group.

As the repeating unit represented by the general formula (P-1-1), the following repeating units represented by the general formulae (P-1-1a) to (P-1-1f) and the like are preferable, and the repeating unit represented by the general formula (P-1-1d-1) is particularly preferable.

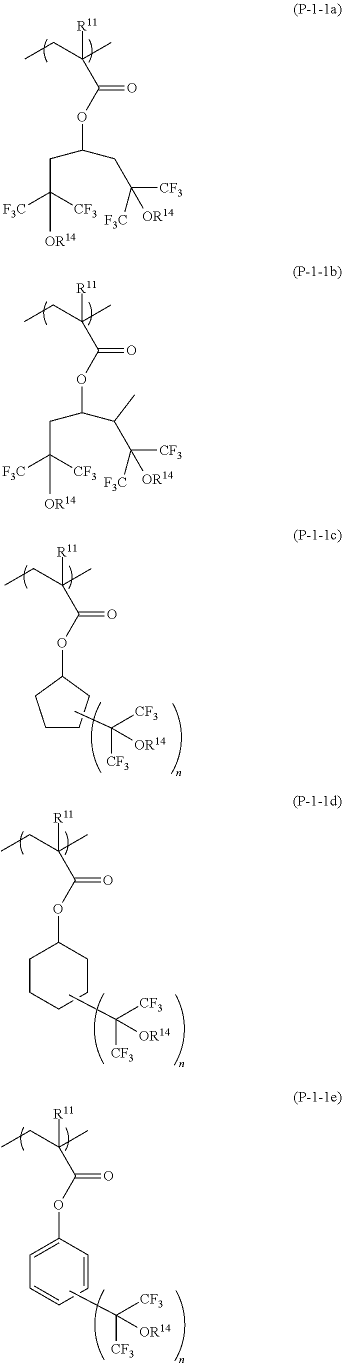

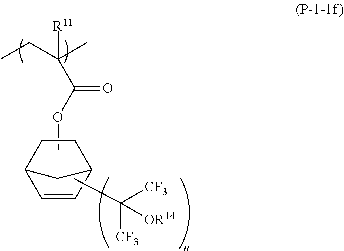

(In the general formulae (P-1-1a) to (P-1-1f), n represents an integer of 1 to 3, R¹¹ represents a hydrogen atom, a methyl group, or a trifluoromethyl group; when n is 1, R¹⁴ represents an acid dissociable group; when n is 2 or 3, R¹⁴ each independently represents a hydrogen atom or an acid dissociable group, and at least one R¹⁴ is an acid dissociable group.)

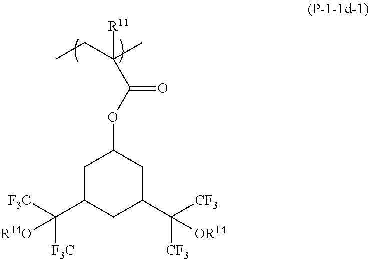

(In the general formula (P-1-1d-1), R¹⁴ each independently represents a hydrogen atom or an acid dissociable group, and at least one R¹⁴ is an acid dissociable group;)

The description given above in connection with R¹⁴ in the general formula (P-1) may be applied to R¹⁴ in the general formulae (P-1-1a) to (P-1-1f) and (P-1-1d-1).

Examples of the repeating unit represented by the general formula (P-1) include the following repeating unit represented by the general formula (P-1-2).

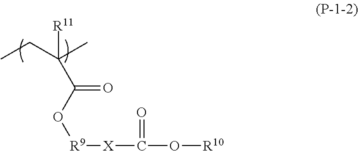

(In the general formula (P-1-2), R¹¹ represents a hydrogen atom, a methyl group, or a trifluoromethyl group, R⁹ represents a single bond, or a divalent, and linear, branched, or cyclic, and saturated or unsaturated hydrocarbon group having 1 to 20 carbon atoms,

X represents a methylene group substituted with a fluorine atom or a linear or branched fluoroalkylene group having 2 to 20 carbon atoms, and R¹⁰ represents an acid dissociable group.)

The description given above in connection with X, R¹³ and R¹⁴ in the general formula (P-1) may be applied to X, R⁹ and R¹⁰ in the general formula (P-1-2), respectively.

Additionally, specific examples of R⁹ in the general formula (P-1-2) include the following groups represented by the structure (c1) to (c27). The symbol “*” in the structure (c1) to (c27) indicates a bonding site.

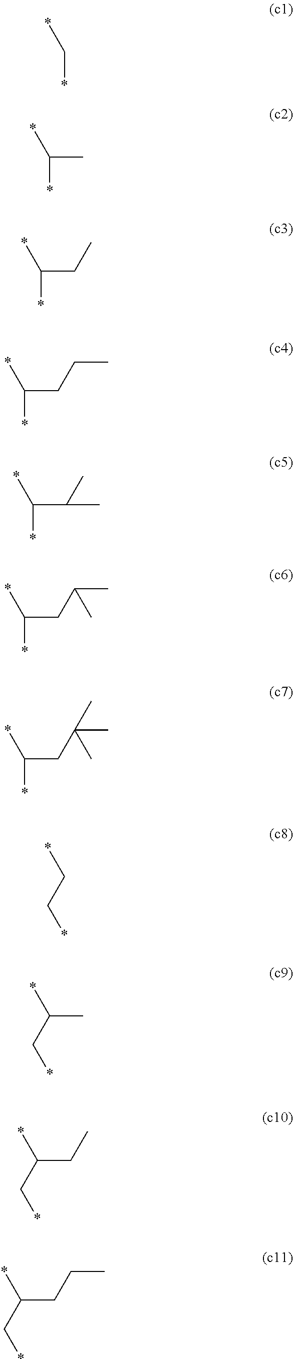

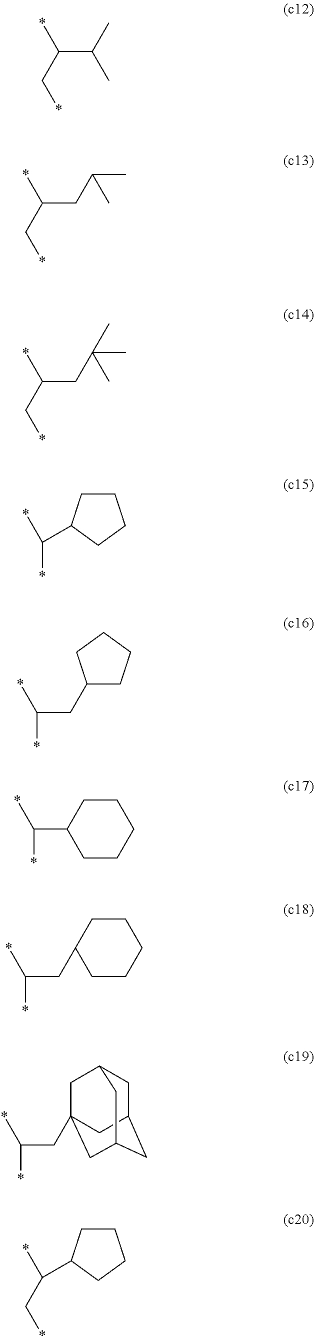

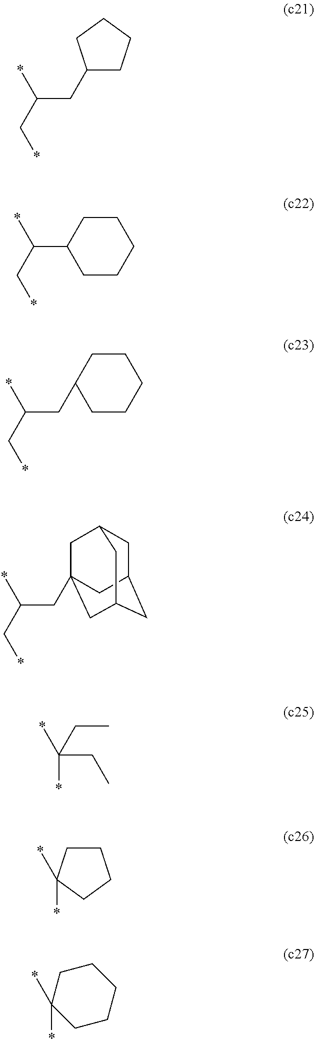

In particular, R⁹ in the general formula (P-1-2) is preferably a methylene group, an ethylene group, a 1-methyethylene group, a 2-methylethylene group, and a divalent alicyclic hydrocarbon group having 4 to 20 carbon atoms, or a group derived therefrom.

Additionally, R¹⁰ in the general formula (P-1-2) is preferably a t-butoxycarbonyl group, an alkoxy substituted methyl group, and a group represented by the general formula [—C(R)₃],

Examples of the repeating unit represented by the general formula (P-1) include the following repeating unit represented by the general formula (P-1-3).

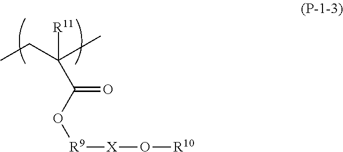

(In the general formula (P-1-3), R¹¹ represents a hydrogen atom, a methyl group, or a trifluoromethyl group, R⁹ represents a single bond, or a divalent, and linear, branched, or cyclic, and saturated or unsaturated hydrocarbon group having 1 to 20 carbon atoms, X represents a methylene group substituted with a fluorine atom or a linear or branched fluoroalkylene group having 2 to 20 carbon atoms, and R¹⁰ represents an acid dissociable group.)

The description given above in connection with X and R¹⁴ in the general formula (P-1) may be applied to X and R¹⁰ in the general formula (P-1-3), respectively. In addition, the description given above in connection with R⁹ in the general formula (P-1-2) may be applied to R⁹ in the general formula (P-1-3).

The polymer (A) may have only one kind of the repeating unit (P1) or two or more kinds thereof.

The repeating unit (P2) is not specifically limited so long as it has a fluorine atom in the side chain but no acid dissociable group. The following repeating unit represented by the general formula (P-2) is preferable.

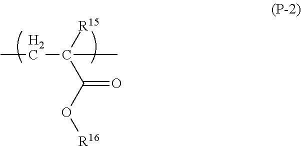

(In the general formula (P-2), R¹⁵ represents a hydrogen atom, a methyl group, or a trifluoromethyl group, R¹⁶ represents a linear or branched alkyl group having 1 to 6 carbon atoms in which at least one hydrogen atom is substituted with a fluorine atom, an alicyclic hydrocarbon group having 4 to 20 carbon atoms in which at least one hydrogen atom is substituted with a fluorine atom, or a group derived therefrom.)

Examples of R¹⁶ that is a group in which at least one hydrogen atom in the linear or branched alkyl group having 1 to 6 carbon atoms in the general formula (P-2) is substituted with a fluorine atom, include a partially fluorinated alkyl group of an alkyl group such as a methyl group, an ethyl group, a 1-propyl group, a 2-propyl group, a 1-butyl group, a 2-butyl group, a 2-(2-methylpropyl) group, a 1-pentyl group, a 2-pentyl group, a 3-pentyl group, a 1-(2-methylbutyl) group, a 1-(3-methylbutyl) group, a 2-(2-methylbutyl) group, a 2-(3-methylbutyl) group, a neopentyl group, a 1-hexyl group, a 2-hexyl group, a 3-hexyl group, a 1-(2-methylpentyl) group, a 1-(3-methylpentyl) group, a 1-(4-methylpentyl) group, a 2-(2-methylpentyl) group, a 2-(3-methylpentyl) group, a 2-(4-methylpentyl) group, a 3-(2-methylpentyl) group, and a 3-(3-methylpentyl) group; a perfluoroalkyl group; and the like.

Examples of R¹⁶ that is a group in which at least one hydrogen atom is substituted with a fluorine atom in the alicyclic hydrocarbon group having 4 to 20 carbon atoms or a group derived therefrom include a partially fluorinated hydrocarbon group of an alicyclic hydrocarbon group such as a cyclopentyl group, a cyclopentylmethyl group, a 1-(1-cyclopentylethyl) group, a 1-(2-cyclopentylethyl) group, a cyclohexyl group, a cyclohexylmethyl group, a 1-(1-cyclohexylethyl) group, a 1-(2-cyclohexylethyl group), cycloheptyl group, a cycloheptylmethyl group, a 1-(1-cycloheptylethyl) group, a 1-(2-cycloheptylethyl) group, and a 2-norbornyl group; or a group derived therefrom; a perfluorohydrocarbon group; and the like.

Preferable examples of a monomer for providing the repeating unit represented by the general formula (P-2) include (meth)acrylic acid trifluoromethyl ester, (meth)acrylic acid 2,2,2-trifluoroethyl ester, (meth)acrylic acid perfluoroethyl ester, (meth)acrylic acid perfluoro n-propyl ester, (meth)acrylic acid perfluoro i-propyl ester, (meth)acrylic acid perfluoro n-butyl ester, (meth)acrylic acid perfluoro i-butyl ester, (meth)acrylic acid perfluoro t-butyl ester, (meth)acrylic acid 2-(1,1,1,3,3,3-hexafluoropropyl)ester, (meth)acrylic acid 1-(2,2,3,3,4,4,5,5-octafluoropentyl)ester, methyl(meth)acrylic acid perfluorocyclohexyl ester, (meth)acrylic acid 1-(2,2,3,3,3-pentafluoropropyl)ester, (meth)acrylic acid 1-(3,3,4,4,5,5,6,6,7,7,8,8,9,9,10,10,10-heptadecafluomdecyl)ester, (meth)acrylic acid 1-(5-trifluoromethyl-3,3,4,4,5,6,6,6-octafluorohexyl)ester, and the like.

The polymer (A) may have only one kind of the repeating unit (P2) or two or more kinds thereof.

In the case where the polymer (A) contains the repeating unit (P2), which has no acid dissociable group in the side chain, as the fluorine atom-containing repeating unit, the polymer (A) has a repeating unit having an acid dissociable group in the side chain (hereinafter, also referred to as “repeating unit (Q)”).

The repeating unit (Q) is not specifically limited so long as it has an acid dissociable group in the side chain but no fluorine atom. It is preferably the following repeating unit represented by the general formula (Q-1).

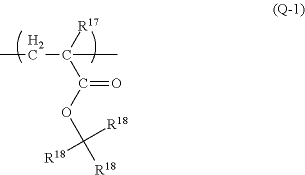

(In the general formula (Q-1), R¹⁷ represents a hydrogen atom, a methyl group, or a trifluoromethyl group, R¹⁸ each independently represents a linear or branched alkyl group having 1 to 4 carbon atoms, a monovalent alicyclic hydrocarbon group having 4 to 20 carbon atoms, or a group derived therefrom, or any two of R¹⁸ bind to each other and form, together with the carbon atom to which they are attached, a divalent alicyclic hydrocarbon group having 4 to 20 carbon atoms, or a group derived therefrom, and the remaining one R¹⁸ represents a linear or branched alkyl group having 1 to 4 carbon atoms, a monovalent alicyclic hydrocarbon group having 4 to 20 carbon atoms, or a group derived therefrom.)

The description given above in connection with the acid dissociable group represented by [—C(R)₃] may be applied to [C(R¹⁸)₃] in the general formula (Q-1).

The polymer (A) may have only one kind of the repeating unit (Q) or two or more kinds thereof.

The polymer (A) of the present invention may contain, in addition to the repeating unit (1); the fluorine atom-containing repeating unit such as the repeating unit (P1) and the repeating unit (P2); and the repeating unit (Q) described above, one kind or two or more kinds of other repeating units.

Examples of the other repeating unit include a repeating unit having a lactone skeleton capable of increasing alkali solubility, a repeating unit having a cyclic carbonate structure (i.e. cyclic carbonic acid ester structure) capable of generating a carboxyl group by the action of an acid to increase dissolution contrast after exposure to light, and the like.

Examples of the repeating unit having a lactone skeleton include the repeating unit represented by the following general formula (2), the repeating unit represented by the following general formula (3), and the like.

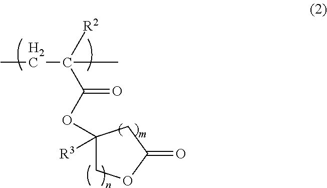

(In the general formula (2), R² represents a hydrogen atom, a methyl group, or a trifluoromethyl group, R³ represents a linear or branched alkyl group having 1 to 4 carbon atoms, m represents an integer of 1 to 3, and n represents an integer of 1 to 3.)

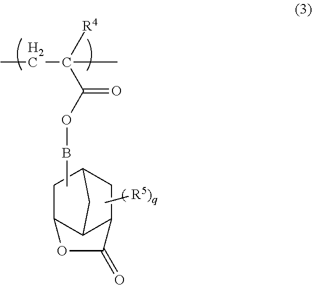

(In the general formula (3), R⁴ represents a hydrogen atom, a methyl group, or a trifluoromethyl group, R⁵ represents a hydrogen atom, a linear or branched alkyl group having 1 to 4 carbon atoms, a linear or branched fluorinated alkyl group having 1 to 4 carbon atoms, or a linear or branched alkoxyl group having 1 to 4 carbon atoms, q represents an integer of 0 to 3, B represents a single bond, an ether group, an ester group, a carbonyl group, a divalent chained hydrocarbon group having 1 to 30 carbon atoms, a divalent alicyclic hydrocarbon group having 3 to 30 carbon atoms, a divalent aromatic hydrocarbon group having 6 to 30 carbon atoms, or a divalent group obtained by combination thereof.)

Examples of the linear or branched alkyl group having 1 to 4 carbon atoms as R³ in the general formula (2) include a methyl group, an ethyl group, a n-propyl group, an i-propyl group, a n-butyl group, a 1-methylpropyl group, a t-butyl group, and the like.

In the general formula (2), m is an integer of 1 to 3, and preferably 1 or 2.

In the general formula (2), n is an integer of 1 to 3, and preferably 1 or 2.

The preferable examples of the monomer for providing the repeating unit represented by the general formula (2) include the following compounds represented by the general formula (M-2-1) and (M-2-2), and the like.

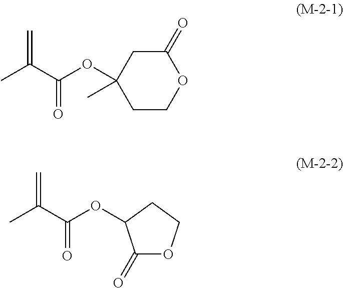

The polymer (A) may have only one kind of the repeating unit (P2) or two or more kinds thereof.

Examples of the linear or branched alkyl group having 1 to 4 carbon atoms as R⁵ in the general formula (3) include a methyl group, an ethyl group, a n-propyl group, an i-propyl group, a n-butyl group, a 1-methylpropyl group, a t-butyl group, and the like.

Examples of the linear or branched, and fluorinated alkyl group having 1 to 4 carbon atoms as R⁵ include a group in which part or all of the hydrogen atoms in an alkyl group having 1 to 4 carbon atoms are substituted with a fluorine atom.

Examples of the linear or branched alkoxyl group having 1 to 4 carbon atoms as R⁵ include a methoxy group, an ethoxy group, a n-propoxy group, an i-propoxy group, a n-butoxy group, a 2-methylpropoxy group, a 1-methylpropoxy group, a t-butoxy group, and the like.

In the general formula (3), q is an integer of 0 to 3, and preferably 0 to 2.

Examples of the divalent chained hydrocarbon group having 1 to 30 carbon atoms as B in the general formula (3) include a linear alkylene group such as a methylene group, an ethylene group, a 1,2-propylene group, a 1,3-propylene group, a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, a tetradecamethylene group, a pentadecamethylene group, a hexadecamethylene group, a heptadecamethylene group, an octadecamethylene group, a nonadecamethylene group, and an icosylene group; and a branched alkylene group such as a 1-methyl-1,3-propylene group, a 2-methyl-1,3-propylene group, a 2-methyl-1,2-propylene group, a 1-methyl-1,4-butylene group, a 2-methyl-1,4-butylene group, a methylidene group, an ethylidene group, a propylidene group, and a 2-propylidene group; and the like.

Examples of the divalent alicyclic hydrocarbon group having 3 to 30 carbon atoms as B in the general formula (3) include a monocyclic cycloalkylene group such as a 1,3-cyclobutylene group, a 1,3-cyclopentylene group, a 1,4-cyclohexylene group, and a 1,5-cyclooctylene group; a polycyclic cycloalkylene group such as a 1,4-norbornylene group, a 2,5-norbornylene group, a 1,5-adamantylene group, and 2,6-adamantylene group; and the like.

Examples of the divalent aromatic hydrocarbon group having 6 to 30 carbon atoms as B in the general formula (3) include an arylene group such as a phenylene group, a tolylene group, a naphthylene group, a phenanthrylene group, and an anthrylene group; and the like.

The preferable examples of the monomer for providing the repeating unit represented by the general formula (3) include the following compounds represented by the general formula (M-3-1) and (M-3-3), and the like.

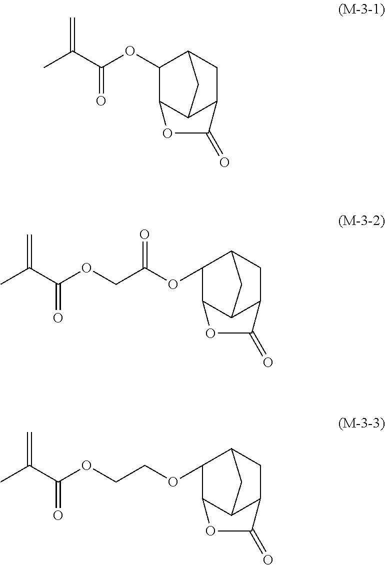

The polymer (A) may have only one kind of the repeating unit represented by the general formula (3) or two or more kinds thereof.

Examples of the repeating unit having a cyclic carbonate structure include the following repeating unit represented by the general formula (4), and the like.

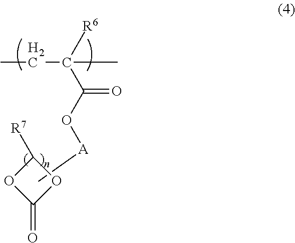

(In the general formula (4), R⁶ represents a hydrogen atom, a methyl group, or a trifluoromethyl group, R⁷ each independently represents a hydrogen atom, a chained hydrocarbon group having 1 to 5 carbon atoms, A represents a single bond, a divalent or trivalent chained hydrocarbon group having 1 to 30 carbon atoms, a divalent or trivalent alicyclic hydrocarbon group having 3 to 30 carbon atoms, or a divalent or trivalent aromatic hydrocarbon group having 6 to 30 carbon atoms; when A is trivalent, a carbon atom included in A and a carbon atom constituting the cyclic carbonic acid ester bind to each other thereby to form a ring structure, and n represents an integer of 2 to 4.)

In the general formula (4), n is an integer of 2 to 4. Specifically, the cyclic carbonate structure has a 5-membered ring structure when n is 2 (ethylene group), a 6-membered ring structure when n is 3 (propylene group), and a 7-membered ring structure when n is 4 (butylene group).

In the general formula (4), A represents a single bond, a divalent or trivalent, substituted or unsubstituted chained hydrocarbon group having 1 to 30 carbon atoms, a divalent or trivalent, substituted or unsubstituted alicyclic hydrocarbon group having 3 to 30 carbon atoms which may have a heteroatom, or a divalent or trivalent, substituted or unsubstituted aromatic hydrocarbon group having 6 to 30 carbon atoms, When A is a single bond, an oxygen atom of the (meth)acrylic acid which constitutes the polymer and a carbon atom forming the cyclic carbonate structure are directly bonded to each other.

The chained hydrocarbon group means a hydrocarbon group which consists of only a chain structure without having any cyclic structure in main chain.

Examples of the divalent chained hydrocarbon group having 1 to 30 carbon atoms include a linear alkylene group such as a methylene group, an ethylene group, a 1,2-propylene group, a 1,3-propylene group, a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, a tetradecamethylene group, a pentadecamethylene group, a hexadecamethylene group, a heptadecamethylene group, an octadecamethylene group, a nonadecamethylene group, and an icosylene group; and a branched alkylene group such as a 1-methyl-1,3-propylene group, a 2-methyl-1,3-propylene group, a 2-methyl-1,2-propylene group, a 1-methyl-1,4-butylene group, a 2-methyl-1,4-butylene group, a methylidene group, an ethylidene group, a propylidene group, and a 2-propylidene group; and the like.

Examples of the trivalent chained hydrocarbon group having 1 to 30 carbon atoms include a group from which one hydrogen atom in the functional group is eliminated.

A specific structure for a case in which A is a chained hydrocarbon group is a structure in which an oxygen atom of the (meth)acrylic acid constituting the polymer and a carbon atom forming the cyclic carbonate structure are bonded to each other via a linear alkyl group having 1 to 5 carbon atoms (see, the repeating unit (4-1) to (4-6) shown below). Further, the chained hydrocarbon group may have a substituent group (see, the repeating unit (4-16) shown below).

It is also possible that the carbon atom included in A and the carbon which constituting the cyclic carbonate structure bind to each other to form a ring structure. In other words, the cyclic carbonate structure may form a part of a bridged ring, a fused ring, or a Spiro ring. When two carbon atoms from the cyclic carbonate structure are included in a ring structure, a bridged ring or a fused ring is formed. When only one carbon atom from the cyclic carbonic acid ester is included in a ring structure, a spiro ring is formed. The repeating units (4-7), (4-9), (4-11), (4-12), (4-15), and (4-17) to (4-22) described below are examples of a fused ring (5- to 6-membered ring) wherein a carbon atom included in A and two carbon atoms forming the cyclic carbonate structure are included. Meanwhile, the repeating unit (4-10) and (4-14) described below are examples of a spiro ring wherein a carbon atom included in A and one carbon atom forming the cyclic carbonate structure are included. The ring structure may be also a heterocycle which contains a heteroatom such as an oxygen (O) atom and a nitrogen (N) atom (see, the repeating unit (4-17) to (4-22) described below). Meanwhile, the repeating unit (4-8) and (4-13) described below are examples of a bridged ring in which two carbon atoms included in A and two carbon atoms forming the cyclic carbonate structure are included.

The term “alicyclic hydrocarbon group” means a hydrocarbon group which contains, in the ring structure, only an alicyclic hydrocarbon structure but no aromatic structure, with the proviso that, it is not necessarily required for the alicyclic hydrocarbon group to be constituted only with an alicyclic hydrocarbon structure, and it may have a chained structure in the part thereof.

Examples of the divalent alicyclic hydrocarbon group include a monocyclic cycloalkylene group such as a 1,3-cyclobutylene group, a 1,3-cyclopentylene group, a 1,4-cyclohexylene group, and a 1,5-cyclooctylene group; a polycyclic cycloalkylene group such as a 1,4-norbornylene group, a 2,5-norbornylene group, a 1,5-adamantylene group, and 2,6-adamantylene group; and the like.

Examples of the trivalent alicyclic hydrocarbon group include a group from which one hydrogen atom in the functional group is eliminated, and the like.

Examples of the structure for a case in which A is an alicyclic hydrocarbon group include a structure in which an oxygen atom of (meth)acrylic acid constituting the polymer and a carbon atom constituting the cyclic carbonic acid ester are bonded to each other via a cyclopentylene group (see, the repeating unit (4-10) described below), a structure in which the bonding is made via a norbornylene group (see, the repeating units (4-11) and (4-12) described below), a structure in which the bonding is made via a substituted tetradecahydrophenanthryl group (see, the repeating unit (4-14) described below), and the like.

Further, the repeating units (4-11) and (4-12) described below are examples of a fused ring (4- or 5-membered ring) in which a carbon atom included in A and two carbon atoms constituting the cyclic carbonic acid ester are included. Meanwhile, the repeating units (4-10) and (4-14) described below are examples of a Spiro ring that is formed with a carbon atom included in A and a carbon atom constituting the cyclic carbonic acid ester.

The term “aromatic hydrocarbon group” means a hydrocarbon group which contains, in the ring structure, an aromatic ring structure, with the proviso that, it is not necessarily required for the aromatic hydrocarbon group to be constituted only with an aromatic ring structure, and it may have a chained structure or an alicyclic hydrocarbon structure in the part thereof.

Examples of the divalent aromatic hydrocarbon group include an arylene group such as a phenylene group, a tolylene group, a naphthylene group, a phenanthrylene group, and an anthrylene group; and the like.

Examples of the trivalent aromatic hydrocarbon group include a group from which one hydrogen atom in the functional group is eliminated, and the like.

Examples of the structure for a case in which A is an aromatic hydrocarbon group include a structure in which an oxygen atom of a (meth)acrylic acid constituting the polymer and a carbon atom constituting the cyclic carbonic acid ester are bonded to each other via a benzylene group (see, the repeating unit (4-15) described below), and the like. The repeating unit (4-15) is an example of a fused ring (6-membered ring) in which a carbon atom included in A and two carbon atoms constituting the cyclic carbonate structure are included.

A monomer for giving the repeating unit represented by the general formula (4) may be synthesized by a method known in the prior art, for example the method described in Tetrahedron Letters, Vol. 27, No. 32 p. 3741 (1986) or Organic Letters, Vol. 4, No. 15 p. 2561 (2002).

As the repeating unit represented by the general formula (4), the following repeating units (4-1) to (4-22) that are represented by the general formula (4-1) to (4-22) respectively are particularly preferred. It is noted that R⁶ in the general formula (4-1) to (4-22) has the same meaning as R⁶ in the general formula (4).

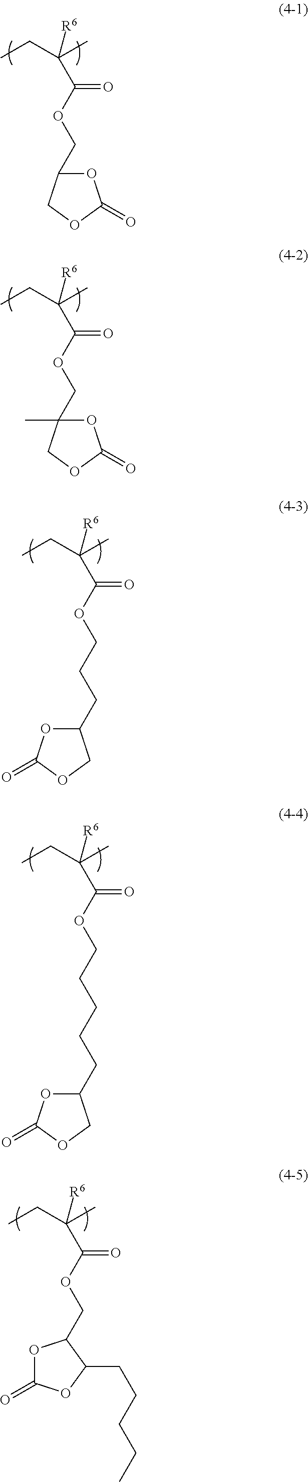

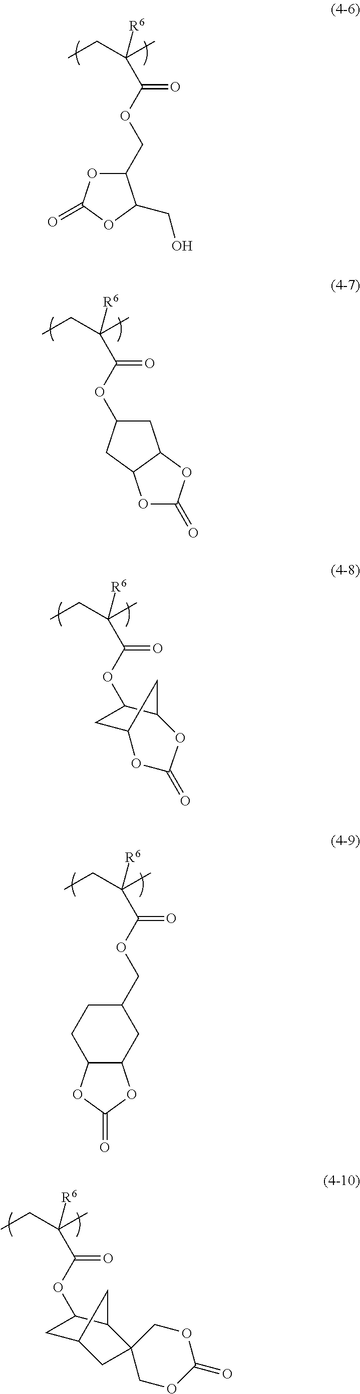

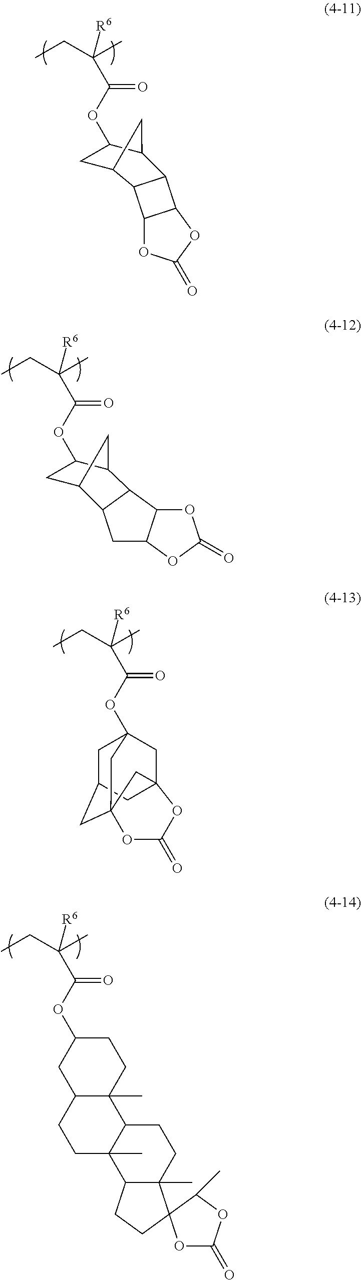

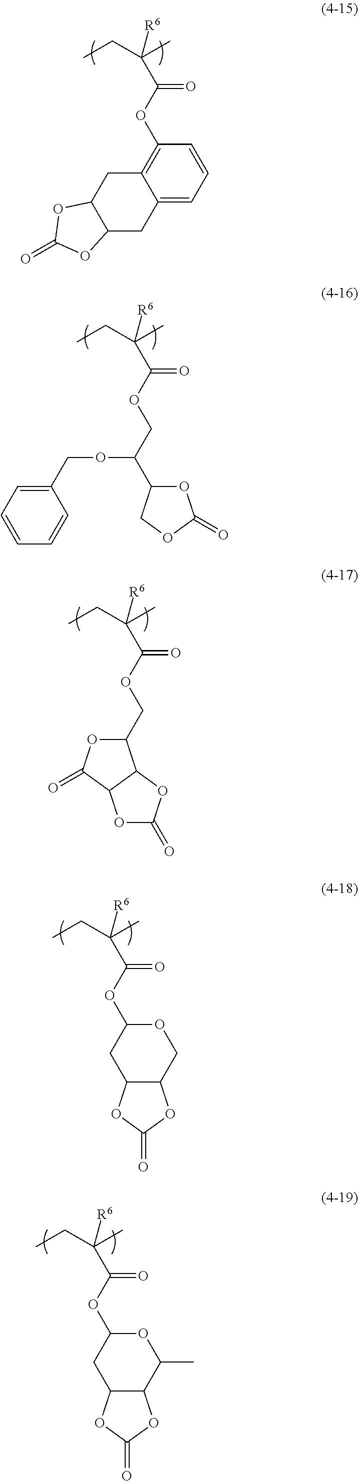

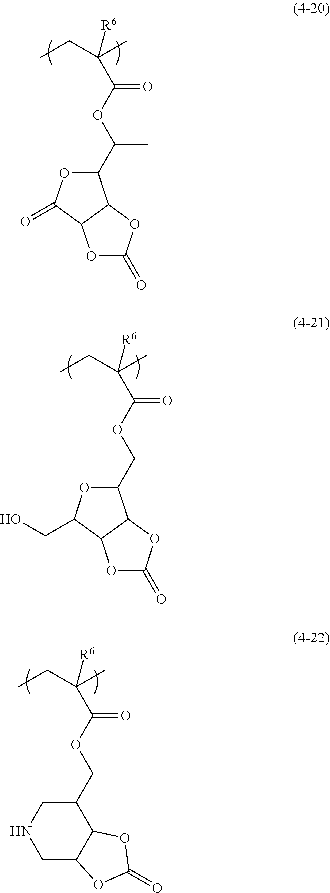

The polymer (A) may have only one kind of the repeating unit (4) or two or more kinds thereof

The polymer (A) preferably contains at least one of the repeating units that are represented by the general formula (2) to (4).

Hereinafter, a preferable content ratio of each repeating unit is given below when the total of the repeating units contained in the polymer (A) of the present invention is 100% by mol.

The content ratio of the repeating unit (1) is preferably in the range from 1% to 10% by mol, more preferably from 1% to 7% by mol, and further preferably from 1% to 5% by mol. If the content ratio is less than 1% by mol, the generating amount of acid to cause the deprotection reaction may become insufficient. On the other hand, if it is more than 10% by mol, irradiated light may not fully reach the bottom part of a resist.

The content ratio of the repeating unit (P1) (i.e., a fluorine atom-containing repeating unit) is preferably in the range from 5% to 50% by mol, more preferably from 5% to 40% by mol, and further preferably from 5% to 30% by mol. If the content ratio is less than 5% by mol, the sufficient water repelling effect may not be obtained. On the other hand, if it is more than 50% by mol, the water repelling effect is too high so that, at the time of development, a developer may not be applied on a resist pattern after the light exposure.

The content ratio of the repeating unit (P2) (i.e., a fluorine atom-containing repeating unit) is preferably in the range from 5% to 30% by mol, more preferably from 5% to 25% by mol, and further preferably from 10% to 20% by mol. If the content ratio is less than 5% by mol, the developer is repelled at the time of development, and as a result the resist pattern may not be formed after the light exposure. On the other hand, if it is more than 30% by mol, the water repelling effect is too high so that, at the time of development, a developer may not be applied on a resist pattern after the light exposure.

The total content ratio of the fluorine atom-containing repeating units is preferably in the range from 5% to 50% by mol, more preferably from 5% to 40% by mol, and further preferably from 5% to 30% by mol. If the content ratio is less than 5% by mol, the developer is repelled at the time of development, and as a result the resist pattern may not be formed after the light exposure. On the other hand, if it is more than 50% by mol, the water repelling effect is too high so that, at the time of development, a developer may not be applied on a resist pattern after the light exposure.

The content ratio of the repeating unit (Q) (i.e., a repeating unit containing an acid dissociable group) is preferably in the range from 20% to 80% by mol, more preferably from 30% to 70% by mol, and further preferably from 35% to 70% by mol. If the content ratio is less than 20% by mol, sufficient alkali solubility of a developer may not be obtained after light exposure. On the other hand, if the content ratio is more than 80% by mol, the alkali solubility of a developer becomes so large after light exposure, and therefore the pattern shape may be lost.

The content ratio of the repeating unit represented by the general formula (2) (i.e., other repeating unit) is generally 80% or less by mol, preferably in the range from 20% to 80% by mol, and further preferably from 30% to 70% by mol. If the content ratio is 80% or less by mol, sufficient alkali solubility can be obtained.

The content ratio of the repeating unit represented by the general formula (3) (i.e., other repeating unit) is generally 80% or less by mol, preferably in the range from 20% to 80% by mol, and further preferably from 30% to 70% by mel. If the content ratio is 80% or less by mol, sufficient alkali solubility can be obtained.

The content ratio of the repeating unit represented by the general formula (4) (i.e., other repeating unit) is generally 80% or less by mot, preferably in the range from 20% to 80% by mol, and further preferably from 30% to 70% by mol. If the content ratio is 80% or less by mol, sufficient alkali solubility can be obtained.

The total content ratio of these other repeating units is generally 80% or less by mol, and more preferably in the range from 1% to 70% by mol. If the total content ratio of other repeating units is more than 80% by mol, sufficient solubility in a resist solvent may not be obtained.

The polymer (A) of the present invention can be produced by polymerizing polymerizable unsaturated monomers corresponding to each specified repeating unit in the presence of a chain transfer agent as required, using a radical polymerization initiator such as a hydroperoxide, a dialkyl peroxide, a diacyl peroxide, and an azo compound in an appropriate solvent.

Examples of the solvent used for polymerization include an alkane such as n-pentane, n-hexane, n-heptane, n-octane, n-nonane, and n-decane; a cycloalkane such as cyclohexane, cycloheptane, cyclooctane, decalin and norbornane; an aromatic hydrocarbon such as benzene, toluene, xylene, ethyl benzene, and cumene; a halogenated hydrocarbon such as chlorobutanes, bromohexanes, dichloroethanes, hexamethylene dibromide and chlorobenzene; a saturated carboxylic acid ester such as ethyl acetate, n-butyl acetate, i-butyl acetate, and methyl propionate; a ketone such as acetone, 2-butanone, 4-methyl-2-pentanone and 2-heptanone; an ether such as tetrahydrofuran, dimethoxyethanes and diethoxyethanes; an alcohol such as methanol, ethanol, 1-propanol, 2-propanol, and 4-methyl-2-pentanol; and the like. These solvents may be used singly or in combination of two or more types thereof.

The polymerization temperature is generally in the range from 40° C. to 150° C., and preferably from 50° C. to 120° C. The reaction time is generally in the range from 1 to 48 hours, and preferably from 1 to 24 hours.

Additionally, the polystyrene-reduced weight average molecular weight (hereinafter, referred to as “Mw”) of the polymer (A) in the present invention determined by gel permeation chromatography (GPC) is preferably in the range from 1,000 to 50,000, more preferably from 1,000 to 40,000, and still more preferably from 1,000 to 30,000. If the Mw of the polymer (A) is less than 1,000, a sufficient receding contact angle may not be obtained. On the other hand, if the Mw of the polymer (A) exceeds 50,000, the developability of the resulting resist may deteriorate.

The ratio (Mw/Mn) of the Mw to the polystyrene-reduced number average molecular weight (hereinafter, referred to as “Mn”) of the polymer (A) determined by GPC is generally in the range from 1 to 5, and preferably from 1 to 4.

It is preferable that the polymer (A) contains almost no impurities such as halogens and metals. That can provide a resist leading to improved sensitivity, resolution, process stability, pattern shape and the like.

The polymer (A) can be purified by a chemical purification method such as washing with water and liquid-liquid extraction, a combination of the chemical purification method and a physical purification method such as ultrafiltration and centrifugation.

The radiation sensitive resin composition of the present invention may contain one kind of the polymer (A) or two or more kinds thereof.

The radiation sensitive resin composition of the present invention may contain, in addition to the polymer (A), other polymer (A2) as a resin component.

Examples of the other polymer (A2) include a resin having an alicyclic skeleton such as norbornane ring in the main chain obtained by polymerization of a norbornene derivative and the like, a resin having a norbornane ring and a maleic anhydride derivative in the main chain obtained by copolymerization of a norbornene derivative and maleic anhydride, a resin having a norbornane ring and a (meth)acrylic skeleton in the main chain obtained by copolymerization of a norbornene derivative and a (meth)acrylic compound, a resin having a norbornane ring, a maleic anhydride derivative and a (meth)acrylic skeleton in the main chain obtained by copolymerization of a norbornene derivative, a maleic anhydride and a (meth)acrylic compound, a resin having a (meth)acrylic skeleton in the main chain obtained by copolymerization of a (meth)acrylic compound, and the like.

In the present invention, the content of the polymer (A1) is preferably more than 50% by mass, more preferably in the range from 50% to 100% by mass, and further preferably from 55% to 100% by mass, based on 100% by mass of the entire resin component (A) contained in the radiation sensitive resin composition of the present invention. When the content of the polymer (A1) is more than 50% by mass, excellent sensitivity and LWR can be obtained and development defects can be sufficiently inhibited, being favorable.

Mw of the polymer (A2) determined by GPC is particularly limited and is preferably in the range from 1,000 to 50,000, more preferably from 1,000 to 40,000, and further preferably from 1,000 to 30,000.

The ratio (Mw/Mn) of the Mw to Mn of the polymer (A2) determined by GPC is generally in the range from 1 to 5, and preferably from 1 to 4.

The radiation sensitive resin composition of the present invention may contain one kind of the polymer (A2) or two or more kinds thereof.

### <Solvent (B)>

The radiation sensitive resin composition of the present invention is usually prepared in the form of a composition solution by dissolving the solid content in a solvent so that the total solid content is usually in the range from 1% to 50% by mass, and preferably from 1% to 25% by mass, and then filtering the solution with a filter having a pore diameter of about 0.2 μm, for example.

Examples of the solvent (B) include a linear or branched ketone such as 2-butanone, 2-pentanone, 3-methyl-2-butanone, 2-hexanone, 4-methyl-2-pentanone, 3-methyl-2-pentanone, 3,3-dimethyl-2-butanone, 2-heptanone, and 2-octanone; a cyclic ketone such as cyclopentanone, 3-methylcyclopentanone, cyclohexanone, 2-methylcyclohexanone, 2,6-dimethylcyclohexanone, and isophorone; a propylene glycol monoalkyl ether acetate such as propylene glycol monomethyl ether acetate, propylene glycol monoethyl ether acetate, propylene glycol mono-n-propyl ether acetate, propylene glycol mono-1-propyl ether acetate, propylene glycol mono-n-butyl ether acetate, propylene glycol mono-1-butyl ether acetate, propylene glycol mono-sec-butyl ether acetate, and propylene glycol mono-t-butyl ether acetate; an alkyl 2-hydroxypropionate such as methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate, and t-butyl 2-hydroxypropionate; an alkyl 3-alkoxypropionate such as methyl 3-methoxypropionate, ethyl 3-methoxypropionate, methyl 3-ethoxypropionate, and ethyl 3-ethoxypropionate; n-propyl alcohol, i-propyl alcohol, n-butyl alcohol, t-butyl alcohol, cyclohexanol, ethylene glycol monomethyl ether, ethylene glycol monoethyl ether, ethylene glycol mono-n-propyl ether, ethylene glycol mono-n-butyl ether, diethylene glycol dimethyl ether, diethylene glycol diethyl ether, diethylene glycol di-n-propyl ether, diethylene glycol di-n-butyl ether, ethylene glycol monomethyl ether acetate, ethylene glycol monoethyl ether acetate, ethylene glycol mono-n-propyl ether acetate, propylene glycol monomethyl ether, propylene glycol monoethyl ether, propylene glycol mono-n-propyl ether, toluene, xylene, 2-hydroxy-2-methylethylpropionate, ethyl ethoxyacetate, ethyl hydroxyacetate, methyl 2-hydroxy-3-methylbutyrate, 3-methoxybutyl acetate, 3-methyl-3-methoxybutyl acetate, 3-methyl-3-methoxybutyl propionate, 3-methyl-3-methoxybutyl butyrate, ethyl acetate, n-propyl acetate, n-butyl acetate, methyl acetoacetate, ethyl acetoacetate, methyl pyruvate, ethyl pyruvate, N-methylpyrrolidone, N,N-dimethylformamide, N,N-dimethylacetamide, benzyl ethyl ether, di-n-hexyl ether, diethylene glycol monomethyl ether, diethylene glycol monoethyl ether, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, and the like.

Of these, a linear or branched ketone, a cyclic ketone, a propylene glycol monoalkyl ether acetate, an alkyl 2-hydroxypropionate, an alkyl 3-alkoxypropionate, γ-butyrolactone, and the like are preferable.

The solvent (B) may be used singly or in combination of two or more types thereof.

### <Nitrogen Containing Compound>

The radiation sensitive resin composition of the present invention may contain, in addition to the polymer (A) and the solvent (B), a nitrogen containing compound.

The nitrogen containing compound is a component which controls the diffusion phenomenon of an acid generated from the polymer (A) and the acid generator upon exposure in the resist film and inhibits the undesired chemical reactions in the unexposed area. When the acid diffusion controller is blended, storage stability of the resulting radiation sensitive resin composition is improved. In addition, resolution in a resist may be further improved and changing of a resist pattern line width due to the fluctuation of post-exposure delay (PED) from exposure to post-exposure heat treatment can be suppressed, whereby a composition with remarkably superior process stability can be obtained.

Examples of the nitrogen containing compound include a tertiary amine compound, other amine compounds, an amide group-containing compound, a urea compound, a nitrogen containing heterocyclic compound, and the like.

The nitrogen containing compound may be used singly or in combination of two or more types thereof.

The amount of the acid diffusion controller to be blended is usually 15 parts or less by mass, preferably 10 parts or less by mass, and further preferably 5 parts or less by mass, based on 100 parts by mass of the polymer (A). If the amount of the acid diffusion controller to be blended exceeds 15 parts by mass, sensitivity in a resist tends to be lowered. On the other hand, if the amount of the acid diffusion controller to be blended is less than 0.001 parts by mass, the pattern shape or dimensional fidelity in a resist may be decreased depending on the processing conditions.

### <Radiation Sensitive Acid Generator>

The radiation sensitive resin composition of the present invention may contain, in addition to the polymer (A), the solvent (B), and the nitrogen containing compound, a radiation sensitive acid generator.

The radiation sensitive acid generator (hereinafter, also referred to as “acid generator”) generates an acid upon exposure. The acid generator causes dissociation of an acid-dissociable group in an acid-dissociable group containing repeating unit which is present in a resin component (elimination of a protective group) due to an acid generated upon exposure, so that the exposed area of the resist film becomes readily soluble in an alkaline developer. This makes it possible to form a positive-tone resist pattern.

As the acid generator, the following compound represented by the general formula (5) is preferably contained.

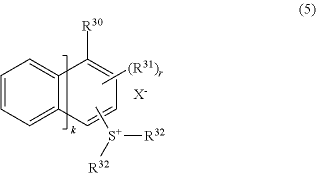

In the general formula (5), R³⁰ represents a hydrogen atom, a fluorine atom, a hydroxyl group, a linear or branched alkyl group having 1 to 10 carbon atoms, a linear or branched alkoxyl group having 1 to 10 carbon atoms, or a linear or branched alkoxycarbonyl group having 2 to 11 carbon atoms.

Additionally, R³¹ represents a linear or branched alkyl group having 1 to 10 carbon atoms, a linear or branched alkoxyl group having 1 to 10 carbon atoms, or a linear, branched, or cyclic alkanesulfonyl group having 1 to 10 carbon atoms.

Further, R³² individually represent a linear or branched alkyl group having 1 to 10 carbon atoms, a substituted or unsubstituted phenyl group, a substituted or unsubstituted naphtyl group, or a substituted or unsubstituted divalent group having 2 to 10 carbon atoms by binding two R³².

Moreover, k is an integer from 0 to 2, X⁻ represents an anion represented by R³³CₙF₂ₙSO₃⁻ (wherein R³³ represents a fluorine atom, or a substituted or unsubstituted hydrocarbon group having 1 to 12 carbon atoms, and n is an integer from 1 to 10), and r is an integer from 1 to 10.

Examples of the linear or branched alkyl group having 1 to 10 carbon atoms represented by R³⁰, R³¹, and R³² in the general formula (5) include a methyl group, an ethyl group, a n-propyl group, an i-propyl group, a n-butyl group, a 2-methylpropyl group, a 1-methylpropyl group, a t-butyl group, a n-pentyl group, a neopentyl group, a n-hexyl group, a n-heptyl group, a n-octyl group, a 2-ethylhexyl group, a n-nonyl group, a n-decyl group, and the like. Among these, a methyl group, an ethyl group, a n-butyl group, a t-butyl group, and the like are preferable.

Examples of the linear or branched alkoxyl group having 1 to 10 carbon atoms represented by R³⁰ and R³¹ include a methoxy group, an ethoxy group, a n-propoxy group, an i-propoxy group, a n-butoxy group, a 2-methylpropoxy group, a 1-methylpropoxy group, a t-butoxy group, a n-pentyloxy group, a neopentyloxy group, a n-hexyloxy group, a n-heptyloxy group, a n-octyloxy group, a 2-ethylhexyloxy group, a n-nonyloxy group, a n-decyloxy group, and the like. Among these, a methoxy group, an ethoxy group, a n-propoxy group, a n-butoxy group, and the like are preferable.

Examples of the linear or branched alkoxycarbonyl group having 2 to 11 carbon atoms represented by R³⁰ include a methoxycarbonyl group, an ethoxycarbonyl group, a n-propoxycarbonyl group, an i-propoxycarbonyl group, a n-butoxycarbonyl group, a 2-methylpropoxycarbonyl group, a 1-methylpropoxycarbonyl group, a t-butoxycarbonyl group, a n-pentyloxycarbonyl group, a neopentyloxycarbonyl group, a n-hexyloxycarbonyl group, a n-heptyloxycarbonyl group, a n-octyloxycarbonyl group, a 2-ethylhexyloxycarbonyl group, a n-nonyloxycarbonyl group, a n-decyloxycarbonyl group, and the like. Among these, a methoxycarbonyl group, an ethoxycarbonyl group, a n-butoxycarbonyl group, and the like are preferable.

Examples of the linear, branched, or cyclic alkanesulfonyl group having 1 to 10 carbon atoms represented by R³¹ include a methanesulfonyl group, an ethanesulfonyl group, a n-propanesulfonyl group, a n-buthanesulfonyl group, a tert-butanesulfonyl group, a n-pentanesulfonyl group, a neopentanesulfonyl group, a n-hexanesulfonyl group, a n-heptanesulfonyl group, a n-octanesulfonyl group, a 2-ethylhexanesulfonyl group, a n-nonanesulfonyl group, a n-decanesulfonyl group, a cyclopentanesulfonyl group, a cyclohexanesulfonyl group, and the like. Among these, a methanesylfonyl group, an ethanesulfonyl group, a n-propanesulfonyl group, a n-butanesulfonyl group, a cyclopentansulfonyl group, a cyclohexanesulfonyl group, and the like are preferable.

Additionally, r in the general formula (5) is preferably 0 to 2.

Examples of the substituted or unsubstituted phenyl group represented by R³² in the general formula (5) include a phenyl group; a phenyl group substituted with a linear, branched, or cyclic alkyl group having 1 to 10 carbon atoms, such as an o-tolyl group, an m-tolyl group, a p-tolyl group, a 2,3-dimethylphenyl group, a 2,4-dimethylphenyl group, a 2,5-dimethylphenyl group, a 2,6-dimethylphenyl group, a 3,4-dimethylphenyl group, a 3,5-dimethylphenyl group, a 2,4,6-trimethylphenyl group, a 4-ethylphenyl group, a 4-t-butylphenyl group, a 4-cyclohexylphenyl group, or a 4-fluorophenyl group; a group obtained by substituting a phenyl group or the alkyl-substituted phenyl group with at least one group selected from a hydroxyl group, a carboxyl group, a cyano group, a nitro group, an alkoxyl group, an alkoxyalkyl group, an alkoxycarbonyl group, and an alkoxycarbonyloxy group; and the like.

Examples of the alkoxyl group as a substituent for a phenyl group or the alkyl-substituted phenyl group include linear, branched, or cyclic alkoxyl groups having 1 to 20 carbon atoms, such as a methoxy group, an ethoxy group, a n-propoxy group, an i-propoxy group, a n-butoxy group, a 2-methylpropoxy group, a 1-methylpropoxy group, a t-butoxy group, a cyclopentyloxy group, and a cyclohexyloxy group, and the like.

Among the substituent group, examples of the alkoxyalkyl group include linear, branched, or cyclic alkoxyalkyl groups having 2 to 21 carbon atoms, such as a methoxymethyl group, an ethoxymethyl group, a 1-methoxyethyl group, a 2-methoxyethyl group, a 1-ethoxyethyl group, and a 2-ethoxyethyl group, and the like.

Among the substituent group, examples of the alkoxycarbonyl group include linear, branched, or cyclic alkoxycarbonyl groups having 2 to 21 carbon atoms, such as a methoxycarbonyl group, an ethoxycarbonyl group, a n-propoxycarbonyl group, an i-propoxycarbonyl group, a n-butoxycarbonyl group, a 2-methylpropoxycarbonyl group, a 1-methylpropoxycarbonyl group, a t-butoxycarbonyl group, a cyclopentyloxycarbonyl group, and a cyclohexyloxycarbonyl group, and the like.

Among the substituent group, examples of the alkoxycarbonyloxy group include linear, branched, or cyclic alkoxycarbonyloxy groups having 2 to 21 carbon atoms, such as a methoxycarbonyloxy group, an ethoxycarbonyloxy group, a n-propoxycarbonyloxy group, an i-propoxycarbonyloxy group, a n-butoxycarbonyloxy group, a t-butoxycarbonyloxy group, a cyclopentyloxycarbonyl group, a cyclohexyloxycarbonyl group, and the like.

Among the above substituted or unsubstituted phenyl groups, a phenyl group, a 4-cyclohexylphenyl group, a 4-t-butylphenyl group, a 4-methoxyphenyl group, a 4-t-butoxyphenyl group, and the like are particularly preferable.

Examples of the substituted or unsubstituted naphthyl group represented by R³² include a naphthyl group; naphthyl groups substituted with a linear, branched, or cyclic alkyl group having 1 to 10 carbon atoms, such as a 2-methyl-1-naphthyl group, a 3-methyl-1-naphthyl group, a 4-methyl-1-naphthyl group, a 5-methyl-1-naphthyl group, a 6-methyl-1-naphthyl group, a 7-methyl-1-naphthyl group, a 8-methyl-1-naphthyl group, a 2,3-dimethyl-1-naphthyl group, a 2,4-dimethyl-1-naphthyl group, a 2,5-dimethyl-1-naphthyl group, a 2,6-dimethyl-1-naphthyl group, a 2,7-dimethyl-1-naphthyl group, a 2,8-dimethyl-1-naphthyl group, a 3,4-dimethyl-1-naphthyl group, a 3,5-dimethyl-1-naphthyl group, a 3,6-dimethyl-1-naphthyl group, a 3,7-dimethyl-1-naphthyl group, a 3,8-dimethyl-1-naphthyl group, a 4,5-dimethyl-1-naphthyl group, a 5,8-dimethyl-1-naphthyl group, a 4-ethyl-1-naphthyl group, a 2-naphthyl group, a 1-methyl-2-naphthyl group, a 3-methyl-2-naphthyl group, and a 4-methyl-2-naphthyl group; a group obtained by substituting a naphthyl group or the alkyl-substituted naphthyl group with at least one group selected from a hydroxyl group, a carboxyl group, a cyano group, a nitro group, an alkoxyl group, an alkoxyalkyl group, an alkoxycarbonyl group, and an alkoxycarbonyloxy group; and the like.

Examples of the alkoxyl group, the alkoxyalkyl group, the alkoxycarbonyl group, and the alkoxycarbonyloxy group as a substituent for a naphthyl group or the alkyl-substituted naphthyl group include the groups mentioned above in connection with a phenyl group and the alkyl-substituted phenyl group.

Among the above substituted or unsubstituted naphthyl groups, a 1-naphthyl group, a 1-(4-methoxynaphthyl) group, a 1-(4-ethoxynaphthyl) group, a 1-(4-n-propoxynaphthyl) group, a 1-(4-n-butoxynaphthyl) group, a 2-(7-methoxynaphthyl) group, a 2-(7-ethoxynaphthyl) group, a 2-(7-n-propoxynaphthyl) group, a 2-(7-n-butoxynaphthyl) group, and the like are particularly preferable.

The divalent group having 2 to 10 carbon atoms formed when two R³² bond to each other is preferably a group that forms a five or six-membered ring (particularly preferably a five-membered ring (i.e., tetrahydrothiophene ring)) together with the sulfur atom of the general formula (5).

Examples of a substituent for the divalent group include the groups (e.g., hydroxyl group, carboxyl group, cyano group, nitro group, alkoxyl group, alkoxyalkyl group, alkoxycarbonyl group, and alkoxycarbonyloxy group) mentioned above in connection with a phenyl group and the alkyl-substituted phenyl group.

R³² in the general formula (5) is particularly a methyl group, an ethyl group, a phenyl group, a 4-methoxyphenyl group, a 1-naphthyl group, a divalent group in which two R³² bond to each other to form a tetrahydrothiophene ring structure together with the sulfur atom, and the like.

CₙF₂ₙ⁻ group in the R³³CₙF₂ₙSO₃⁻ anion represented by X⁻ in the general formula (5) is a perfluoroalkyl group having n carbon atoms. This group may be either linear or branched, n is preferably 1, 2, 4, or 8.

The substituted or unsubstituted hydrocarbon group having 1 to 12 carbon atoms represented by R³³ is preferably an alkyl group having 1 to 12 carbon atoms, a cycloalkyl group, and a bridged alicyclic hydrocarbon group.

Specific example thereof include a methyl group, an ethyl group, a n-propyl group, an i-propyl group, a n-butyl group, a 2-methylpropyl group, a 1-methylpropyl group, a t-butyl group, a n-pentyl group, a neopentyl group, a n-hexyl group, a cyclohexyl group, a n-heptyl group, a n-octyl group, a 2-ethylhexyl group, a n-nonyl group, a n-decyl group, a norbornyl group, a norbornylmethyl group, a hydroxynorbornyl group, an adamantyl group, and the like.

Specific examples of the preferable compound represented by the general formula (5) include triphenylsulfonium trifluoromethane sulfonate, tri-tert-butylphenylsulfonium trifluoromethane sulfonate, 4-cyclohexylphenyl-diphenylsulfonium trifluoromethane sulfonate, 4-methanesulfonylphenyl-diphenylsulfonium trifluoromethane sulfonate, 1-(3,5-dimethyl-4-hydroxyphenyl)tetrahydrothiopheniumtrifluoromethane sulfonate, 1-(4-n-butoxynaphthyptetrahydrothiopheniumtrifluoromethane sulfonate, triphenylsulfonium perfluoro-n-butane sulfonate, tri-tert-butylphenylsulfonium perfluoro-n-butane sulfonate, 4-cyclohexylphenyl-diphenylsulfonium perfluoro-n-butane sulfonate, 4-methanesulfonylphenyl-diphenylsulfonium perfluoro-n-butane sulfonate, 1-(3,5-dimethyl-4-hydroxyphenyl)tetrahydrothiophenium perfluoro-n-butane sulfonate, 1-(4-n-butoxynaphthyl)tetrahydrothiophenium perfluoro-n-butane sulfonate, triphenylsulfonium perfluoro-n-octane sulfonate, tri-tert-butylphenylsulfonium perfluoro-n-octane sulfonate, 4-cyclohexylphenyl-diphenylsulfonium perfluoro-n-octane sulfonate, 4-methanesulfonylphenyl-diphenylsulfonium perfluoro-n-octane sulfonate, 1-(3,5-dimethyl-4-hydroxyphenyl)tetrahydrothiophenium perfluoro-n-octane sulfonate, 1-(4-n-butoxynaphthyl)tetrahydrothiophenium perfluoro-n-octane sulfonate, triphenylsulfonium 2-(bicyclo [2.2.1]hepta-2′-yl)-1,1,2,2-tetrafluoroethane sulfonate, tri-tert-butylphenylsulfonium 2-(bicyclo[2.2.1]hepta-2′-yl)-1,1,2,2-tetrafluoroethane sulfonate, 4-cyclohexylphenyl-diphenylsulfonium 2-(bicyclo[2.2.1]hepta-2′-yl)-1,1,2,2-tetrafluoroethane sulfonate, 4-methanesulfonylphenyl-diphenylsulfonium 2-(bicyclo[2.2.1]hepta-2′-yl)-1,1,2,2-tetrafluoroethane sulfonate, 1-(3,5-dimethyl-4-hydroxyphenyptetrahydrothiophenium 2-(bicyclo [2.2.1]hepta-2′-yl)-1,1,2,2-tetrafluoroethane sulfonate, 1-(4-n-butoxynaphthyptetrahydrothiophenium 2-(bicyclo[2.2.1]hepta-2′-yl)-1,1,2,2-tetrafluoroethane sulfonate, triphenylsulfonium 2-(bicyclo[2.2.1]hepta-2′-yl)-1,1-difluoroethane sulfonate, tri-tert-butylphenylsulfonium 2-(bicyclo[2.2.1]hepta-2′-yl)-1,1-difluoroethane sulfonate, 4-cyclohexylphenyl-diphenylsulfonium 2-(bicyclo[2.2.1]hepta-2′-yl)-1,1-difluoroethane sulfonate, 4-methanesulfonylphenyl-diphenylsulfonium 2-(bicyclo[2.2.1]hepta-2′-yl)-1,1-difluoroethane sulfonate, 1-(3,5-dimethyl-4-hydroxyphenyl)tetrahydrothiophenium 2-(bicyclo[2.2.1]hepta-2′-yl)-1,1-difluoroethane sulfonate, 1-(4-n-butoxynaphthyptetrahydrothiophenium 2-(bicyclo[2.2.1]hepta-2′-yl)-1,1-difluoroethane sulfonate, and the like.

In the present invention, the acid generator may be used singly or in combination of two or more types thereof.

The amount of the acid generator to be blended is generally 20 parts or less by mass, preferably 15 parts or less by mass, and further preferably 12 parts or less by mass, based on 100 parts by mass of the polymer (A). If the blending amount exceeds 20 parts by mass, the irradiated light may not fully reach the bottom part of a resist film due to the influence of an acid generator.

### <Additives>

The radiation sensitive resin composition of the present invention can be blended with various additives such as an alicyclic additive, a surfactant and a sensitizer, if necessary.

The alicyclic additive is a component which improves the dry etching resistance, the pattern shape, adhesion to a substrate, and the like.

Examples of the alicyclic additive include an adamantane derivative such as 1-adamantanecarboxylate, 2-adamantanone, t-butyl 1-adamantanecarboxylate, t-butoxycarbonylmethyl 1-adamantanecarboxylate, α-butyrolactone 1-adamantanecarboxylate, di-t-butyl 1,3-adamantanedicarboxylate, t-butyl 1-adamantaneacetate, t-butoxycarbonylmethyl 1-adamantaneacetate, di-t-butyl 1,3-adamantanediacetate, and 2,5-dimethyl 2,5-di(adamantylcarbonyloxy)hexane; a deoxycholate such as t-butyl deoxycholate, t-butoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, and mevalonolactone deoxycholate; lithocholates such as t-butyl lithocholate, t-butoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate; alkyl carboxylates such as dimethyl adipate, diethyl adipate, dipropyl adipate, di-n-butyl adipate, and di-t-butyl adipate; a 3-[2-hydroxy-2,2-bis(trifluoromethyl)ethyl]tetracyclo[4.4.0.1^{2,5}.1^{7,10}]dodecane, and the like. The alicyclic additive may be used singly or in combination of two or more types thereof.

The surfactant is a component which improves the applicability, striation, developability, and the like.

Examples of the surfactant include a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, polyethylene glycol distearate, “KP341” (manufactured by Shin-Etsu Chemical Co., Ltd.), “Polyflow No. 75”, and “Polyflow No. 95” (manufactured by Kyoeisha Chemical Co., Ltd.), “EFTOP EF301”, “EFTOP EF303”, and “EFTOP EF352 (manufactured by JEMCO, Inc.), “Megafac F171”, and “Megafac F173” (manufactured by DIC Corporation), “Fluorad FC430”, and “Fluorad FC431” (manufactured by Sumitomo 3M Ltd.), “Asahi Guard AG710”, “Surflon S-382”, “Surflon SC-101”, “Surflon SC-102”, “Surflon SC-103”, “Surflon SC-104”, “Surflon SC-105”, and “Surflon SC-106 (manufactured by Asahi Glass Co., Ltd.), and the like.

The surfactant may be used singly or in combination of two or more types thereof.

The sensitizer is a component which absorbs the energy of radiation, and transmits the energy to the acid generator (B), so that the amount of acid generated by the acid generator (B) increases. The sensitizer thus improves the apparent sensitivity of the radiation-sensitive resin composition.

Examples of the sensitizer include carbazoles, acetophenones, benzophenones, naphthalenes, phenols, biacetyl, cosine, rose bengal, pyrenes, anthracenes, phenothiazines, and the like. The sensitizer may be used singly or in combination of two or more types thereof.

Additionally, when a dye or pigment is blended, the latent image in the exposed area can be visualized, so that the effect of halation during exposure can be reduced. When an adhesion promoter is blended, adhesion to a substrate can be improved.

Further, examples of additive other than ones above include an alkali-soluble resin, a low-molecular-weight alkali solubility controller including an acid-dissociable protecting group, a halation inhibitor, a preservation stabilizer, an antifoaming agent, and the like.

### <Receding Contact Angle>

The radiation sensitive resin composition of the present invention has a receding contact angle of preferably 68 degrees or higher, and more preferably 70 degree or higher, wherein the receding contact angle is an angle between water and a photoresist film which is formed by coating the resin composition on a substrate. When the receding contact angle is lower than 68 degrees, water may not be sufficiently removed during high speed scanning exposure, and therefore a watermark defect may be generated.

The term “receding contact angle” in the present specification refers to a contact angle between a liquid surface and a substrate on which a photoresist film of the resin composition of the present invention is formed, when 25 μl of water is dropped on the substrate and thereafter the water droplet on the substrate is suctioned at a rate of 100/min. Specifically, the receding contact angle can be measured using “DSA-10” (manufactured by KRUS) as described later in Examples.

### <Method of Forming Resist Pattern>

The radiation sensitive resin composition of the present invention is particularly useful for a chemically-amplified resist. In the chemically-amplified resist, an acid dissociable group in the resin component (of mainly, polymer (A)) is dissociated by an action of an acid generated from the acid generator upon exposure, thereby producing a carboxyl group. As a result, solubility of the exposed part of the resist in an alkaline developer is increased, whereby the exposed part is dissolved in the alkaline developer and removed to give a positive type resist pattern.

A specific method for forming a resist pattern is a method including steps of (1) forming a photoresist film on a substrate by using the radiation sensitive resin composition (hereinafter, also referred to as “step (1)”), (2) exposing the photoresist film to light (hereinafter, also referred to as “step (2)”), and (3) forming a resist pattern by developing the exposed photoresist film (hereinafter, also referred to as “step (3)”).

In the step (1), a resin composition solution prepared from the radiation sensitive resin composition of the present invention is applied to a substrate (e.g., silicon wafer or silicon dioxide-coated wafer) by an appropriate application method (e.g., rotational coating, cast coating, or roll coating) to form a resist film. Specifically, the radiation-sensitive resin composition solution is applied so that the resulting resist film has a given thickness, and prebaked (PB) to volatilize the solvent from the film to obtain a resist film.

The thickness of the resist film is not particularly limited, but is preferably in the range from 10 to 5,000 nm, and more preferably from 10 to 2,000 nm.

The prebaking temperature is determined depending on the composition of the radiation-sensitive resin composition, but is preferably about in the range from 30° C. to 200° C., and more preferably from 50° C. to 150° C.

In the step (2), the photoresist film formed in step (1) is subjected to an irradiation process for light exposure of the photoresist film. At that time, it is also possible that the radiation is irradiated by using a liquid immersion medium such as water and the photoresist film is subjected to a liquid immersion exposure process. In this light exposure, radiation is usually applied to the photoresist film via a mask having a given pattern.

As radiation used for liquid immersion lithography, visible rays, ultraviolet rays, deep ultraviolet rays, X-rays, electron beams, or the like are appropriately selected depending on the type of acid generator to be used. It is preferable to use deep ultraviolet rays by ArF excimer laser light (wavelength: 193 nm) or KrF excimer laser light (wavelength: 248 nm). It is particularly preferable use ArF excimer laser light (wavelength: 193 nm).

The exposure conditions are appropriately selected depending on the blending composition of the radiation sensitive resin composition, the type of additives, and the like.

In the present invention, it is preferable to perform post-exposure bake (PEB) after exposure. PEB ensures smooth dissociation of the acid dissociable group in the resin component. PEB conditions are appropriately selected depending on the blending composition of the radiation sensitive resin composition. Heating temperature is normally in the range from 30° C. to 200° C., and preferably from 50° C. to 170° C.

In the present invention, an organic or inorganic antireflective film may be formed on the substrate by the method disclosed in, for example, JP-B H6-12452 (JP-A S59-93448, or the like in order to bring out the potential of the radiation sensitive resin composition to a maximum extent. A protective film may be formed on the resist film by the method disclosed in, for example, JP-A H5-188598, or the like in order to prevent an adverse effect of basic impurities and the like contained in the environmental atmosphere. Further, an immersion liquid protective film may also be formed on the photoresist film by the method disclosed in, for example, JP-A 2005-352384, or the like in order to inhibit evolution of an acid generator from the resist film in liquid immersion exposure process. These methods may be used in combination.

Further, according to the method of forming a resist pattern by the liquid immersion exposure process, a resist pattern can be formed from only a resist film obtained using the radiation sensitive resin composition of the present invention, without forming a protective film (i.e. upper layer film) described above on the resist film. When the resist pattern is formed with an upper layer-free resist film, a step of producing a protective film (i.e. upper layer film) can be omitted, and therefore an improvement in throughput can be expected.

In the step (3), the exposed photoresist film is developed to form a pre-determined resist pattern. It is preferable to use an alkaline aqueous solution prepared by dissolving at least one alkaline compound (e.g., sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene, or 1,5-diazabicyclo-[4.3.0]-5-nonene) in water as a developer.

The concentration of the alkaline aqueous solution is preferably 10% or less by mass. If the concentration of the alkaline aqueous solution exceeds 10% by mass, the unexposed area may also be dissolved in the developer.

An organic solvent may be added to the alkaline aqueous solution (developer).

Examples of the organic solvent include ketones such as acetone, methyl ethyl ketone, methyl i-butyl ketone, cyclopentanone, cyclohexanone, 3-methylcyclopentanone, and 2,6-dimethylcyclohexanone; alcohols such as methyl alcohol, ethyl alcohol, n-propyl alcohol, i-propyl alcohol, n-butyl alcohol, t-butyl alcohol, cyclopentanol, cyclohexanol, 1,4-hexanediol, and 1,4-hexanedimethylol; ethers such as tetrahydrofuran and dioxane; esters such as ethyl acetate, n-butyl acetate, and i-amyl acetate; aromatic hydrocarbons such as toluene and xylene; phenol, acetonylacetone, dimethylformamide, and the like. These organic solvents may be used either individually or in combination.

The organic solvent is preferably used in an amount of 100 vol % or less based on 100 vol % of the alkaline aqueous solution. If the amount of the organic solvent exceeds 100 vol %, the exposed area may remain undeveloped due to a decrease in developability.

An appropriate amount of a surfactant and the like may also be added to the alkaline aqueous solution (developer).

After development using the alkaline aqueous solution (developer), the resist film is normally washed with water, and dried.

### EXAMPLES

Hereinafter, the invention is further described by way of examples. Note that the invention is not limited to the following examples. The unit “parts” refers to “parts by mass”, and the unit “%” refers to “% by weight” unless otherwise indicated.

Measurements and evaluation in the Synthesis Examples are as follows.

### (1) Mn and Mn

The Mw and the Mn based on monodisperse polystyrene were measured by gel permeation chromatography (GPC) using GPC columns manufactured by Tosoh Corp. (G2000HXL×2, G3000HXL×1, G4000HXL×1) under conditions of a flow rate of 1.0 ml/min, eluant of tetrahydrofuran, and column temperature of 40° C. The dispersity “Mw/Mn” was calculated from the results.

### (2) ¹³C-NMR Analysis

Each polymer was subjected to ¹³C-NMR analysis using “JNM-EX270” (manufactured by JEOL Ltd.).

Hereinafter, Synthesis Examples are described.

Each monomer used for the synthesis of the polymers (A-1) to (A-9) and (AR-1) to (AR-3) is shown hereinafter by the general formulae (M-1) to (M-20).

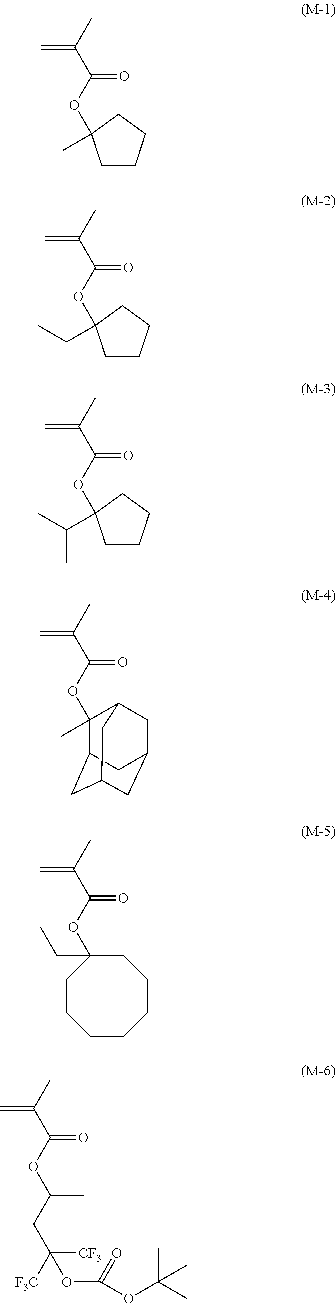

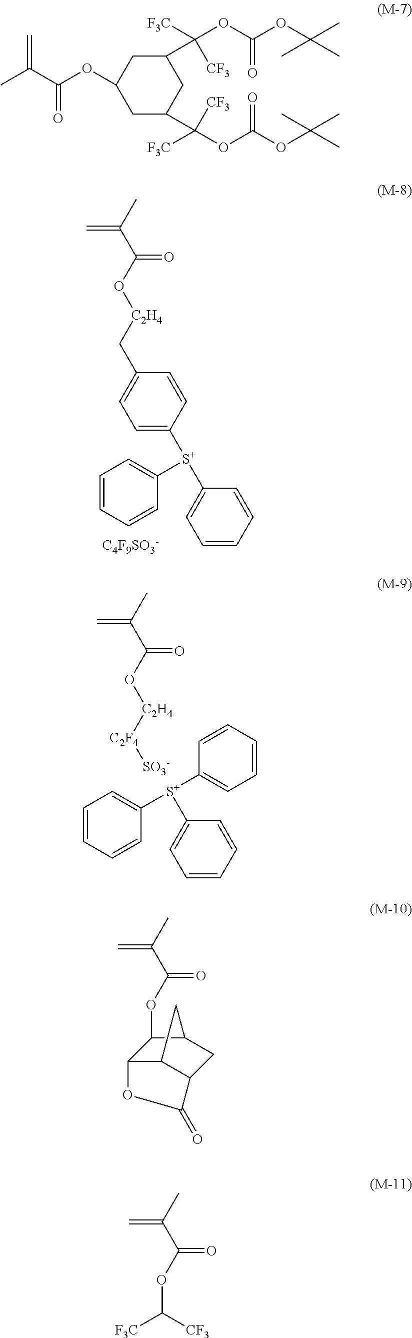

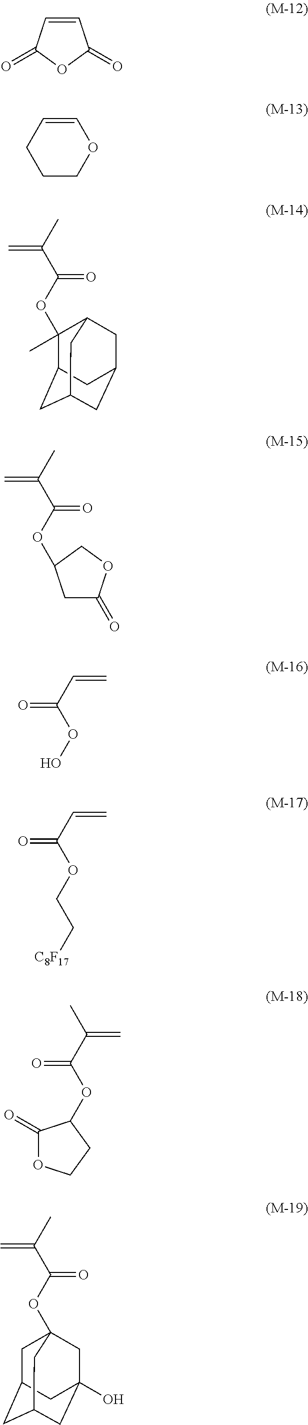

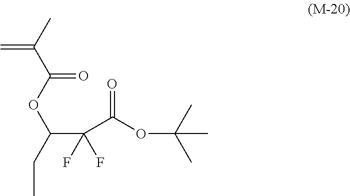

### <Synthesis of Polymers (A-1) to (A-9)>

Monomers and an initiator [2,2′-azobisisobutyronitrile (AIBN)] were used by a combination and a weight corresponding to % by mol according to the general formulation shown in Table 1 and dissolved in 50 g of methyl ethyl ketone to prepare a monomer solution. The total amount of the monomers before starting preparation was adjusted to 50 g. The % by mol of each monomer indicates % by mol in the total amount of the monomers, and the % by mol of each initiator indicates % by mol in the total amount of the monomers and the initiators.

On the other hand, 50 g of methyl ethyl ketone was charged into a 500 ml three-necked flask equipped with a thermometer and a dropping funnel, and then nitrogen was purged for 30 minutes. After that, the content in the flask was heated to a temperature of 80° C. while stirring using a magnetic stirrer.

Subsequently, the above monomer solution was added dropwise to the flask using a dropping funnel over three hours. After the addition, the mixture was aged for three hours, and thereafter allowed to cool to a temperature of 30° C. or lower, thereby obtaining a copolymer solution. After the polymerization, the polymer solution was cooled with water to a temperature of 30° C. or lower and was charged into 1,000 g of methanol. A white precipitate produced was collected by filtration. The white powder collected by filtration was washed twice with 200 g of methanol in a slurry state, filtered again, and dried at a temperature of 50° C. for 17 hours to obtain a polymer in the form of white powder.

Each solution of polymer obtained (% by mass) was analyzed by gas chromatography, and the yield (% by mass) of the polymer and content ratio of each repeating unit in the polymer (% by mol) were measured. The results are shown in Table 2.

TABLE 1

| | | | Addition | | Addition | | Addition | | Addition | Amount |
|---|---|---|---|---|---|---|---|---|---|---|
| | | | amount | | amount | | amount | | amount | of |
| | Polymer | Monomer 1 | (% by mol) | Monomer 2 | (% by mol) | Monomer 3 | (% by mol) | Monomer 4 | (% by mol) | initiator |
| Polymerization | A-1 | M-1 | 46 | M-7 | 10 | M-8 | 3 | M-10 | 41 | 5 |
| example 1 | | | | | | | | | | |
| Polymerization | A-2 | M-2 | 46 | M-7 | 10 | M-8 | 3 | M-10 | 41 | 5 |
| example 2 | | | | | | | | | | |
| Polymerization | A-3 | M-3 | 46 | M-7 | 10 | M-8 | 3 | M-10 | 41 | 5 |
| example 3 | | | | | | | | | | |
| Polymerization | A-4 | M-4 | 46 | M-7 | 10 | M-8 | 3 | M-10 | 41 | 5 |
| example 4 | | | | | | | | | | |
| Polymerization | A-5 | M-5 | 46 | M-7 | 10 | M-8 | 3 | M-10 | 41 | 5 |
| example 5 | | | | | | | | | | |
| Polymerization | A-6 | M-2 | 46 | M-6 | 20 | M-8 | 3 | M-10 | 31 | 5 |
| example 6 | | | | | | | | | | |
| Polymerization | A-7 | M-2 | 46 | M-7 | 10 | M-9 | 3 | M-10 | 41 | 5 |
| example 7 | | | | | | | | | | |
| Polymerization | A-8 | M-2 | 46 | M-11 | 20 | M-8 | 3 | M-10 | 31 | 5 |
| example 8 | | | | | | | | | | |
| Polymerization | A-9 | M-2 | 46 | M-20 | 25 | M-8 | 3 | M-10 | 26 | 5 |
| example 9 | | | | | | | | | | |

TABLE 2

| | | | Monomer 1 | Monomer 2 | Monomer 3 | Monomer 4 |
|---|---|---|---|---|---|---|
| | Polymer | Yield (%) | (% by mol) | (% by mol) | (% by mol) | (% by mol) |
| Polymerization | A-1 | 76.3 | 46.3 | 9.8 | 3.2 | 40.7 |
| example 1 | | | | | | |
| Polymerization | A-2 | 74.5 | 47.2 | 9.7 | 3.1 | 40.0 |
| example 2 | | | | | | |
| Polymerization | A-3 | 73.4 | 47.1 | 9.5 | 3.4 | 40.0 |
| example 3 | | | | | | |
| Polymerization | A-4 | 76.6 | 47.8 | 9.2 | 3.2 | 39.8 |
| example 4 | | | | | | |
| Polymerization | A-5 | 75.0 | 44.8 | 9.8 | 3.6 | 41.8 |
| example 5 | | | | | | |
| Polymerization | A-6 | 74.8 | 46.8 | 19.8 | 3.4 | 30.0 |
| example 6 | | | | | | |
| Polymerization | A-7 | 74.5 | 46.5 | 9.8 | 3.5 | 40.2 |
| example 7 | | | | | | |
| Polymerization | A-8 | 78.5 | 47.0 | 18.5 | 3.5 | 31.0 |
| example 8 | | | | | | |
| Polymerization | A-9 | 76.3 | 46.2 | 24.8 | 3.5 | 25.5 |
| example 9 | | | | | | |

### <Synthesis of Polymer (AR-1)>

A monomer solution was prepared by dissolving 5.14 g (19% by mol) of the monomer (M-12), 9,15 g (29% by mol) of the monomer (M-13), 26.39 g (35% by mol) of the monomer (M-14), and 9.31 g (17% by mol) of the monomer (M-15) in 100 g of 2-butanone, and further charging 0.74 g of dimethyl 2,2′-azobis isobutyrate (MAIB). On the other hand, a three-necked flask having 50 g of 2-butanone charged was purged with nitrogen gas for 30 minutes. After purging nitrogen to the flask, the reaction vessel was heated to a temperature of 80° C. while stirring and the previously prepared monomer solution was added dropwise using a dropping funnel over three hours. The initiation of the addition was set to a polymerization starting time and polymerization reaction was carried out for six hours. After the polymerization, the polymer solution was cooled with water to a temperature of 30° C. or lower and 1,000 g of methanol was charged. A white precipitate produced was collected by filtration. The white powder collected by filtration was washed twice with 200 g of methanol in a slurry state, filtered again, and dried at a temperature of 50° C. for 17 hours to obtain a polymer in the form of white powder (75 g, yield 75%).

The polymer was found to be a copolymer having Mw of 7,200 and Mw/Mn of 1.65. Content ratio of each repeating unit originating from the monomer (M-12), monomer (M-13), monomer (M-14), and monomer (M-15) determined by ¹³C-NMR analysis was 19.2:29.4:34.0:17.4 (% by mol). This polymer is indicated as polymer (AR-1).

### <Synthesis of Polymer (AR-2)>

A monomer solution was prepared by dissolving 7.12 g (50% by mol) of the monomer (M-16) and 42.88 g (50% by mol) of the monomer (M-17) in 100 g of 2-butanone, and further charging 1.91 g of dimethyl 2,2′-azobis isobutyrate (MAIB). On the other hand, a three-necked flask having 50 g of 2-butanone charged was purged with nitrogen gas for 30 minutes. After purging nitrogen to the flask, the reaction vessel was heated to a temperature of 80° C. while stirring and the previously prepared monomer solution was added dropwise using a dropping funnel over three hours. After the dropwise addition, the mixture was aged for 3 hours and then cooled to a temperature of 30° C. or lower to obtain the copolymer solution.

Subsequently, the reaction solution was replaced with a methanol solution by using an evaporator and washed with hexane and water. It was then replaced with propylene glycol monomethyl ether acetate solution by using an evaporator. The solution of polymer obtained (% by mass) was analyzed by gas chromatography, and the yield (% by mass) of the polymer and content ratio of each repeating unit in the polymer (% by mol) were measured. The polymer was found to be a copolymer having Mw of 7,200, and Mw/Mn of 1.72. Content ratio of each repeating unit originating from the monomer (M-16) and monomer (M-17) determined by ¹³C-NMR analysis was 48.2:51.8 (% by mol). This polymer is indicated as polymer (AR-2).

### <Synthesis of Polymer (AR-3)>

A monomer solution was prepared by dissolving 19.3 g (35% by mol) of the monomer (M-14), 16.03 g (40% by mol) of the monomer (M-18), 13.35 g (24% by mol) of the monomer (M-19), and 1.31 g (1% by mol) of the monomer (M-8) in 100 g of 2-butanone, and further charging 2.71 g of dimethyl 2,2′-azobis isobutyrate (MAIB). On the other hand, a three-necked flask having 50 g of 2-butanone charged was purged with nitrogen gas for 30 minutes. After purging nitrogen to the flask, the reaction vessel was heated to a temperature of 80° C. while stirring and the previously prepared monomer solution was added dropwise using a dropping funnel over three hours. The initiation of the addition was set to a polymerization starting time and polymerization reaction was carried out for six hours. After the polymerization, the polymer solution was cooled with water to a temperature of 30° C. or lower and 1,000 g of methanol was charged. A white precipitate produced was collected by filtration. The white powder collected by filtration was washed twice with 200 g of methanol in a slurry state, filtered again, and dried at a temperature of 50° C. for 17 hours to obtain a polymer in the form of white powder (75 g, yield 75%).

The polymer was found to be a copolymer having Mw of 7,100, and Mw/Mn of 1.62. Content ratio of each repeating unit originating from the monomer (M-14), monomer (M-18), monomer (M-19), and monomer (M-8) determined by ¹³C-NMR analysis was 35:40:24:1 (% by mol). This polymer is indicated as resin (AR-3).

### <Preparation of Radiation Sensitive Resin Composition>

The radiation sensitive resin compositions for Example 1 to 9 and Comparative Examples 1 to 3 were prepared by mixing the polymer, acid generator, a nitrogen containing compound, and a solvent according to blending ratio shown in Tables 3 and 4. Components other than the polymers that are described in Tables 3 and 4 are as follows, and “part” in the tables is based on weight.

### <Solvent>

### (B-1): Propylene Glycol Monomethyl Ether Acetate

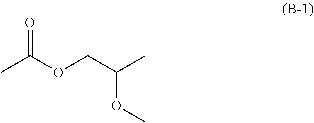

### (B-2): Cyclohexanone

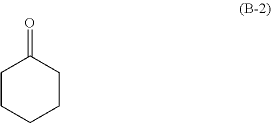

### (B-3): γ-Butyrolactone

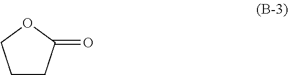

### <Acid Generator>

### (C-1): Compound Described Below

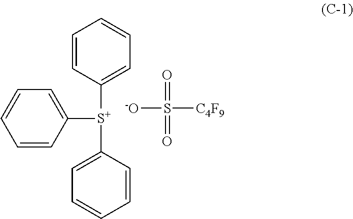

### <Nitrogen Containing Compound>

(D-1): N-t-Butoxycarbonyl-4-hydroxypiperidine

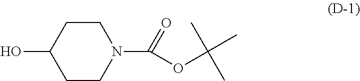

### <Evaluation of Radiation Sensitive Resin Composition>

The radiation sensitive resin compositions according to Examples 1 to 9 and Comparative Examples 1 to 3 were subjected to the following evaluations (1) to (7). Evaluation results are shown in Table 4.

Evaluation method is as follows.

### (1) Measurement of Eluted Amount

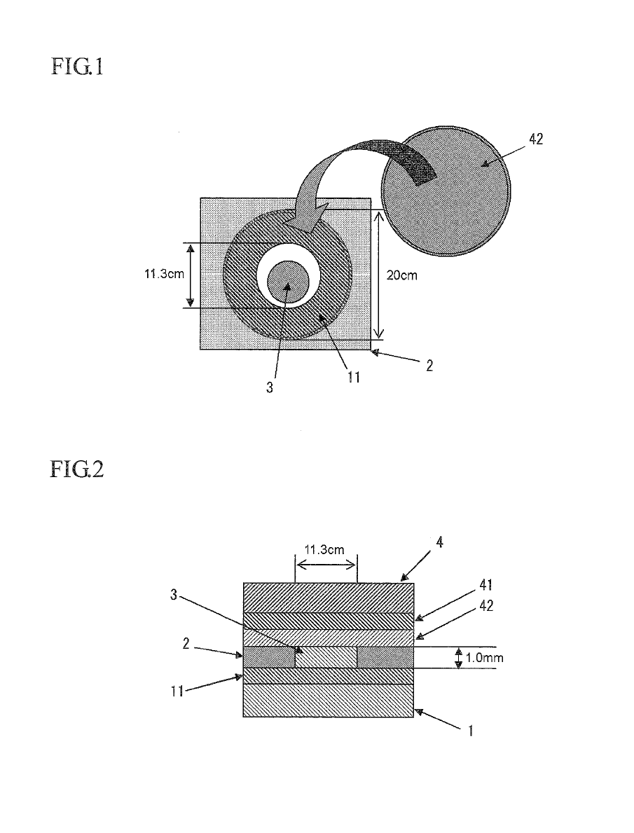

A 30 cm×30 cm square silicone rubber sheet 2 with a thickness of 1.0 mm (manufactured by Kureha Elastomer Co., Ltd.), of which the center was cut out in the form of a disk with a diameter of 11.3 cm, was superposed on the center of an 8-inch silicon wafer 1 which was previously treated with HMDS (hexamethyl disilazane) 11 at a temperature of 100° C. for 60 seconds using “CLEAN TRACK ACTS” (manufactured by Tokyo Electron, Ltd.), as shown in FIG. 1. Subsequently, the cutout area at the center of the silicone rubber sheet was filled with 10 ml of ultra pure water 3 using a 10-ml whole pipette.

After that, a lower layer antireflection film 41 having a thickness of 77 nm (“ARC29A”, manufactured by Brewer Science) was formed on a silicon wafer 4 using “CLEAN TRACK ACT8”, and then each resist composition shown in the Table 3 was spin coated on the lower layer antireflection film 41 and conducted baking at a temperature of 115° C. for 60 seconds using “CLEAN TRACK ACTS” to form a resist film 42 having a thickness of 205 nm. The silicon wafer 4 was superposed on the silicone rubber sheet 2 in a manner such that the resist coating surface comes in contact with the ultra pure water 3, and the ultra pure water 3 does not leak from the silicone rubber 2.

It was held for 10 seconds as it is. Then the 8-inch silicon wafer 4 was removed and the ultra pure water 3 was collected using a glass syringe for use as a sample for analysis. The recovery rate of the ultra pure water after the experiment was 95% or more.

Subsequently, the collected ultra pure water was subjected to a measurement of LC-MS using a liquid chromatograph mass spectrometer having “SERIES 1100” manufactured by AGILENT Corp. for LC section, and “Mariner” manufactured by Perseptive Biosystems, Inc. for MS section under the following conditions to obtain the peak intensity of an anion part of the acid generator. In this instance, peak intensities of the aqueous solutions containing the acid generator at concentrations of 1 ppb, 10 ppb, and 100 ppb were measured under the above measurement conditions to prepare a calibration curve. The eluted amount was calculated from the above peak intensity using this calibration curve.

In the same manner, the peak intensities of aqueous solutions of the acid diffusion controller (nitrogen containing compound) at concentrations of 1 ppb, 10 ppb, and 100 ppb were measured under the same measurement conditions to prepare a calibration curve. The eluted amount of the acid diffusion controller was calculated from the above peak intensity using this calibration curve.

The evaluation criteria were as “bad” when the total eluted amount was 5.0×10¹² mol/cm²/sec or more, and as “good” when the amount was less than 5.0×10⁻¹² mol/cm²/sec.

### (Column Conditions)

Column: One column of “CAPCELL PAK MG” manufactured by Shiseido Co., Ltd.

Flow rate: 0.2 ml/min.

Solvent for elution: 3/7 (volume ratio) mixture of water and methanol, with 0.1% by mass of formic acid added.

Measurement temperature: 35° C.

### (2) Measurement of Receding Contact Angle

A substrate (wafer) wherein a coating film was formed with the radiation sensitive resin composition using “DSA-10” manufactured by KRUS was fabricated.

Promptly after the fabrication, the receding contact angle was measured at room temperature (23° C.) and humidity of 45% under atmospheric pressure according to the following procedure.

First, the position of the wafer stage of the contact angle meter was adjusted, and the substrate was placed on the stage. After injecting water into a needle, the position of the needle was finely adjusted to the initial position at which a waterdrop could be formed on the substrate. Water was then discharged from the needle to form a waterdrop (25 μl) on the substrate. After removing the needle, the needle was moved downward to the initial position, and introduced into the waterdrop. The waterdrop was sucked via the needle for 90 seconds at a rate of 10 μl/min, and the contact angle was measured every second (90 times in total). The average value of twenty contact angle measured values (20 seconds) after the measured value became stable was calculated, and taken as the receding contact angle (°).

### (3) Sensitivity

A lower layer antireflection film having a thickness of 77 nm (“ARC29A” manufactured by Brewer Science) was formed on a 12-inch silicon wafer and the wafer was used as a substrate. For fabricating the lower layer antireflection film, “CLEAN TRACK ACT8” (manufactured by Tokyo Electron Ltd.) was used.

Subsequently, each resin composition shown in Table 3 was subjected to spin coating onto the substrate using “CLEAN TRACK ACT8” and baking (PB) under the conditions shown in Table 4 to form a resist film having a thickness of 120 nm. The resist film was exposed to radiation through a patterned mask using an ArF excimer laser exposure apparatus (“NSR S306C”, manufactured by Nikon Corporation, illuminating conditions: NA=0.78, σ=0.93/0,69). After that, PEB was carried out under the conditions shown in Table 4. The resist film was developed at a temperature of 23° C. for 30 seconds in a tetramethylammonium hydroxide aqueous solution at a concentration of 2.38% by mass, washed with water, and dried to form a positive type resist pattern. An exposure dose at which a 1:1 line·and·space (1L1S) pattern with a line width of 90 nm was formed was taken as an optimum exposure dose, and further this optimum exposure dose was taken as sensitivity. A scanning electron microscope (“S-9380”, manufactured by Hitachi High-Technologies Corporation) was used for the measurement.

### (4) Cross-Sectional Shape of Pattern (Pattern Shape)

The cross-sectional shape of a line·and·space pattern with a line width of 90 nm obtained in (3) above was observed using “S-4800” manufactured by Hitachi High-Technologies Corporation to measure the line width A at the highest part of the pattern and the line width B at the lowest part of the pattern. A rectangular pattern satisfying the relationship between the line width A and the line width B of 0.7<A/B<1 was determined as “good”, and a T-top shape pattern outside the range was determined as “bad.”

### (5) Number of Defects

A lower layer antireflection film having a thickness of 77 nm (“ARC29A” manufactured by Brewer Science) was formed on a 12-inch silicon wafer and the wafer was used as a substrate. For fabricating the lower layer antireflection film, “CLEAN TRACK ACT8” (manufactured by Tokyo Electron Ltd.) was used.

Subsequently, each resin composition shown in Table 3 was subjected to spin coating onto the substrate using “CLEAN TRACK ACTS” and baking (PB) under the conditions shown in Table 4 to form a resist film having a thickness of 120 nm. After that, the resist film was rinsed with pure water for 90 seconds. The resist film was exposed to radiation through a patterned mask under the conditions of NA=0.75, σ=0.85, and ½ annular using an ArF excimer laser liquid immersion exposure apparatus (“NSR S306C”, manufactured by Nikon Corporation). After the exposure, it was rinsed again with pure water for 90 seconds and PEB was carried out under the conditions shown in Table 4. The resist film was developed at a temperature of 23° C. for 60 seconds in a tetramethylammonium hydroxide aqueous solution at a concentration of 2.38% by mass, washed with water, and dried to form a positive type resist pattern. An exposure dose at which a hole pattern with width of 1,000 nm was formed was taken as optimum exposure dose. With the optimum exposure dose, a hole pattern with width of 1,000 nm was formed over the entire surface of the wafer, and the resulting wafer was used as a wafer for evaluating defect. A scanning electron microscope (“S-9380”, manufactured by Hitachi High-Technologies Corporation) was used for the measurement.

After that, the number of defects on hole pattern with a line width of 1,000 nm was measured using “KLA2351” manufactured by KLA-Tencor Corp. In addition, the defects measured by “KLA2351” were observed using a scanning electron microscope (“S-9380”, manufactured by Hitachi High-Technologies Corporation) to classify the defects into those appeared to be originating from resist and those appeared to be originating from foreign matters. When the total number of defects appeared to be originating from resist is 100 or more/wafer, it was determined as “bad.” When it is less than 100/wafer, it was determined as “good.”

The defects appeared to be originating from resist include a residue pattern defect originating from dissolution residues at the time of development, a bump-shape defect originating from dissolved resin residues in a resist solvent, and the like. The defects appeared to be originating from foreign matters include dusts originating from dirt in air, uneven coating and bubbling, etc. that are not related to the resist.

### (6) Pattern Roughness (LWR)

A lower layer antireflection film having a thickness of 77 nm (“ARC29A” manufactured by Brewer Science) was formed on an 8-inch silicon wafer and the wafer was used as a substrate. For fabricating the lower layer antireflection film, “CLEAN TRACK ACT8” (manufactured by Tokyo Electron Ltd.) was used.

Subsequently, each resin composition shown in Table 3 was subjected to spin coating onto the substrate using “CLEAN TRACK ACT8” and baking (PB) under the conditions shown in Table 4 to form a resist film having a thickness of 120 nm. After that, the resist film was rinsed with pure water for 90 seconds. The resist film was exposed to radiation through a patterned mask under the conditions of NA=0.75, σ=0.85, and ½ annular using an ArF excimer laser liquid immersion exposure apparatus (“NSR S306C”, manufactured by Nikon Corporation). After the exposure, it was rinsed again with pure water for 90 seconds and PEB was carried out under the conditions shown in Table 4. The resist film was developed at a temperature of 23° C. for 60 seconds in a tetramethylammonium hydroxide aqueous solution at a concentration of 2.38% by mass, washed with water, and dried to form a positive type resist pattern. At that time, pattern roughness of a line·and·space pattern with width of 100 nm was measured at ten points, and the average value was calculated as LWR. A scanning electron microscope (“S-9380”, manufactured by Hitachi High-Technologies Corporation) was used for the measurement. LWR of 10 or larger was determined as “bad”, while LWR of 10 or smaller was determined as “good.”

### (7) DOF (Depth of Focus)

A lower layer antireflection film having a thickness of 77 nm (“ARC29A” manufactured by Brewer Science) was formed on an 8-inch silicon wafer and the wafer was used as a substrate. For fabricating the lower layer antireflection film, “CLEAN TRACK ACT8” (manufactured by Tokyo Electron Ltd.) was used.

Subsequently, each resin composition shown in Table 3 was subjected to spin coating onto the substrate using “CLEAN TRACK ACT8” and baking (PB) under the conditions shown in Table 4 to form a resist film having a thickness of 120 nm. After that, the resist film was rinsed with pure water for 90 seconds. The resist film was exposed to radiation through a patterned mask under the conditions of NA=0.75, σ=0.85, and ½ annular using an ArF excimer laser liquid immersion exposure apparatus (“NSR S306C”, manufactured by Nikon Corporation). After the exposure, it was rinsed again with pure water for 90 seconds and PEB was carried out under the conditions shown in Table 4. The resist film was developed at a temperature of 23° C. for 60 seconds in a tetramethylammonium hydroxide aqueous solution at a concentration of 2.38% by mass, washed with water, and dried to form a positive type resist pattern. At that time, an exposure dose at which a 100 nm line with line·and·space pattern with a line width of 100 nm was formed was taken as an optimum exposure dose. Thereafter, DOF on an isolated space pattern, which has actual isolated space value of 100 nm with 1S10L having different mask size obtained by the optimum exposure dose, was evaluated. A scanning electron microscope (“S-9380”, manufactured by Hitachi High-Technologies Corporation) was used for the measurement.

TABLE 3

| | | | Nitrogen | |
|---|---|---|---|---|
| | | Acid | containing | |
| | Polymer | generator | compound | Solvent |
| | (parts) | (parts) | (parts) | (parts) |
| Example 1 | A-1(100) | — | D-1(0.65) | B-1(1500) |
| | | | | B-2(650) |
| | | | | B-3(30) |
| Example 2 | A-2(100) | — | D-1(0,65) | B-1(1500) |
| | | | | B-2(650) |
| | | | | B-3(30) |
| Example 3 | A-3(100) | — | D-1(0.65) | B-1(1500) |
| | | | | B-2(650) |
| | | | | B-3(30) |
| Example 4 | A-4(100) | — | D-1(0.65) | B-1(1500) |
| | | | | B-2(650) |
| | | | | B-3(30) |
| Example 5 | A-5(100) | — | D-1(0.65) | B-1(1500) |
| | | | | B-2(650) |
| | | | | B-3(30) |
| Example 6 | A-6(100) | — | D-1(0.65) | B-1(1500) |
| | | | | B-2(650) |
| | | | | B-3(30) |
| Example 7 | A-7(100) | — | D-1(0.65) | B-1(1500) |
| | | | | B-2(650) |
| | | | | B-3(30) |
| Example 8 | A-8(100) | — | D-1(0.65) | B-1(1500) |
| | | | | B-2(650) |
| | | | | B-3(30) |
| Example 9 | A-9(100) | — | D-1(0.65) | B-1(1500) |
| | | | | B-2(650) |
| | | | | B-3(30) |
| Comparative Example 1 | AR-1(100) | c-1(8.5) | D-1(0.65) | B-1(1500) |
| | AR-2(5) | | | B-2(650) |
| | | | | B-3(30) |
| Comparative Example 2 | A-1(100) | c-1(8.5) | D-1(0.65) | B-1(1500) |
| | | | | B-2(650) |
| | | | | B-3(30) |
| Comparative Example 3 | A-3(100) | — | D-1(0.65) | B-1(1500) |
| | | | | B-2(650) |
| | | | | B-3(30) |

TABLE 4

| | Baking | PEB | Eluted | Receding contact | Sensitivity | Pattern | Number of | Pattern | |
|---|---|---|---|---|---|---|---|---|---|
| | (temperature/time) | (temperature/time) | amount | angle (°) | (mJ/cm²) | shape | defects | roughness | DOF |
| Example 1 | 100° C./60 s | 150° C./60 s | Good | 73.1 | 46 | Good | Good | Good | 0.2 |
| Example 2 | 100° C./60 s | 150° C./60 s | Good | 73.9 | 43 | Good | Good | Good | 0.2 |
| Example 3 | 100° C./60 s | 120° C./60 s | Good | 74.2 | 40 | Good | Good | Good | 0.2 |
| Example 4 | 100° C./60 s | 150° C./60 s | Good | 75.1 | 47 | Good | Good | Good | 0.2 |
| Example 5 | 100° C./60 s | 120° C./60 s | Good | 74.8 | 38 | Good | Good | Good | 0.2 |
| Example 6 | 100° C./60 s | 150° C./60 s | Good | 71.7 | 38 | Good | Good | Good | 0.2 |
| Example 7 | 100° C./60 s | 110° C./60 s | Good | 73.2 | 45 | Good | Good | Good | 0.2 |
| Example 8 | 100° C./60 s | 150° C./60 s | Good | 70.8 | 43 | Good | Good | Good | 0.2 |
| Example 9 | 100° C./60 s | 150° C./60 s | Good | 70.4 | 46 | Good | Good | Good | 0.2 |
| Comparative | 100° C./60 s | 110° C./60 s | Good | 80.5 | 40 | Bad | Bad | Bad | 0.1 |
| Example 1 | | | | | | | | | |
| Comparative | 100° C./60 s | 110° C./60 s | Bad | 60.2 | 39 | Bad | Bad | Bad | 0.1 |
| Example 2 | | | | | | | | | |
| Comparative | 100° C./60 s | 120° C./60 s | Bad | 59.5 | 47 | Bad | Bad | Bad | 0.1 |
| Example 3 | | | | | | | | | |

As clearly from the results in Table 4, when the radiation sensitive resin composition added with the novel polymer (A) of the present invention is used, the eluted amount in a liquid for liquid immersion exposure process brought into contact for liquid immersion exposure process is small, and high receding contact angle is provided. As such, a good pattern shape is obtained with low number of defects. Further, it exhibits good pattern roughness and DOF. For such reasons, it is believed that the radiation sensitive resin composition of the present invention can be suitably used for minute lithographic process that will be required in the future.

### EXPLANATION OF THE REFERENCE NUMBERS

1: silicon wafer, 11: hexamethyl disilazane treated layer, 2: silicone rubber sheet, 3: super pure water, 4: silicon wafer, 41: antireflection film, 42: resist film.

1. A radiation sensitive resin composition, comprising:
(A) a polymer comprising a repeating unit represented by the following general formula (1) and a repeating unit having a fluorine atom (provided that said repeating unit represented by the general formula (1) is excluded), and having an acid dissociable group in the side chain; and
(B) a solvent. 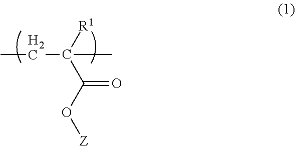
(In the general formula (1), R¹ represents a hydrogen atom, a methyl group, or a trifluoromethyl group, and Z represents a group having a structure which generates an acid when exposed to radiation.)

2. The radiation sensitive resin composition according to claim 1, wherein said polymer (A) further comprises at least one repeating unit selected from the group consisting of a repeating unit represented by the following general formula (2), a repeating unit represented by the following general formula (3), and a repeating unit represented by the following general formula (4). 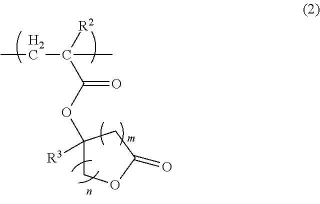
(In the general formula (2), R² represents a hydrogen atom, a methyl group, or a trifluoromethyl group, R³ represents a linear or branched alkyl group having 1 to 4 carbon atoms, m represents an integer of 1 to 3, and n represents an integer of 1 to 3.) 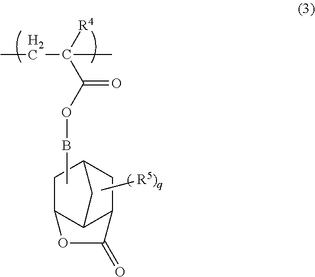
(In the general formula (3), R⁴ represents a hydrogen atom, a methyl group, or a trifluoromethyl group, R⁵ represents a hydrogen atom, a linear or branched alkyl group having 1 to 4 carbon atoms, a linear or branched fluorinated alkyl group having 1 to 4 carbon atoms, or a linear or branched alkoxyl group having 1 to 4 carbon atoms, q represents an integer of 0 to 3, B represents a single bond, an ether group, an ester group, a carbonyl group, a divalent chained hydrocarbon group having 1 to 30 carbon atoms, a divalent alicyclic hydrocarbon group having 3 to 30 carbon atoms, a divalent aromatic hydrocarbon group having 6 to 30 carbon atoms, or a divalent group obtained by combination thereof.) 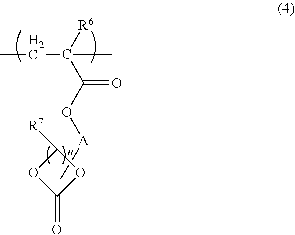
(In the general formula (4), R⁶ represents a hydrogen atom, a methyl group, or a trifluoromethyl group, R⁷ each independently represents a hydrogen atom, a chained hydrocarbon group having 1 to 5 carbon atoms, A represents a single bond, a divalent or trivalent chained hydrocarbon group having 1 to 30 carbon atoms, a divalent or trivalent alicyclic hydrocarbon group having 3 to 30 carbon atoms, or a divalent or trivalent aromatic hydrocarbon group having 6 to 30 carbon atoms; when A is trivalent, a carbon atom included in A and a carbon atom constituting the cyclic carbonic acid ester bind to each other thereby to form a ring structure, and n represents an integer of 2 to 4.)

3. The radiation sensitive resin composition according to claim 1, wherein said polymer (A) comprises, as said repeating unit having a fluorine atom, a repeating unit which has in the side chain, a fluorine atom and an acid dissociable group, as represented by the following general formula (P-1). 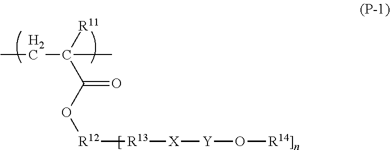
(In the general formula (P-1), n represents an integer of 1 to 3, R¹¹ represents a hydrogen atom, a methyl group, or a trifluoromethyl group, R¹² represents a single bond, or a linear, branched, or cyclic, and saturated or unsaturated hydrocarbon group having (n+1) valency with 1 to 10 carbon atoms, R¹³ represents a single bond or a divalent linear, branched or cyclic, and saturated or unsaturated hydrocarbon group having 1 to 20 carbon atoms, X represents a methylene group substituted with a fluorine atom, or a linear or branched fluoroalkylene group having 2 to 20 carbon atoms, Y represents a single bond or —CO—; when n is 1, R¹⁴ represents an acid dissociable group; when n is 2 or 3, R¹⁴ each independently represents a hydrogen atom or an acid dissociable group, and at least one R¹⁴ is an acid dissociable group.)

4. The radiation sensitive resin composition according to claim 1, wherein said polymer (A) comprises, as said repeating unit having a fluorine atom, a repeating unit which has a fluorine atom in the side chain, as represented by the following general formula (P-2), and wherein said polymer (A) further comprises a repeating unit having an acid dissociable group in the side chain, as represented by the following general formula (Q-1). 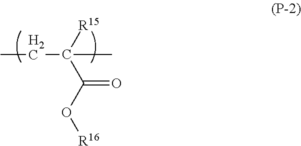
(In the general formula (P-2), R¹⁵ represents a hydrogen atom, a methyl group, or a trifluoromethyl group, R¹⁶ represents a linear or branched alkyl group having 1 to 6 carbon atoms in which at least one hydrogen atom is substituted with a fluorine atom, an alicyclic hydrocarbon group having 4 to 20 carbon atoms in which at least one hydrogen atom is substituted with a fluorine atom, or a group derived therefrom.) 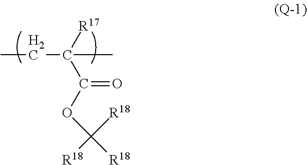
(In the general formula (Q-1), R¹⁷ represents a hydrogen atom, a methyl group, or a trifluoromethyl group, R¹⁸ each independently represents a linear or branched alkyl group having 1 to 4 carbon atoms, a monovalent alicyclic hydrocarbon group having 4 to 20 carbon atoms, or a group derived therefrom, or any two of R¹⁵ bind to each other and form, together with the carbon atom to which they are attached, a divalent alicyclic hydrocarbon group having 4 to 20 carbon atoms, or a group derived therefrom, and the remaining one R¹⁸ represents a linear or branched alkyl group having 1 to 4 carbon atoms, a monovalent alicyclic hydrocarbon group having 4 to 20 carbon atoms, or a group derived therefrom.)

5. The radiation sensitive resin composition according to claim 1, wherein said repeating unit represented by the general formula (1) is at least one repeating unit selected from the group consisting of a repeating unit represented by the following general formula (1-1) and a repeating unit represented by the following general formula (1-2). 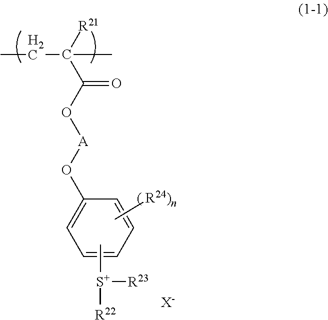
(In the general formula (1-1), R²¹ represents a hydrogen atom, a methyl group, or a trifluoromethyl group, R²², R²³ and R²⁴ each independently represent a linear or branched alkyl group having 1 to 10 carbon atoms which may have a substituent group, a linear or branched alkoxyl group having 1 to 10 carbon atoms which may have a substituent group, or an aryl group having 3 to 10 carbon atoms which may have a substituent group, n represents an integer of 0 to 3, A represents a methylene group, a linear or branched alkylene group having 2 to 10 carbon atoms, or an arylene group having 3 to 10 carbon atoms, X⁻ represents a counter ion of S⁺.) 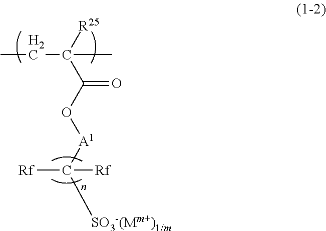
(In the general formula (1-2), R²⁵ represents a hydrogen atom, a methyl group, or a trifluoromethyl group, Rf represents a fluorine atom or a linear or branched perfluoroalkyl group having 1 to 10 carbon atoms, A¹ represents a single bond, or a divalent organic group, and M^{m+} represents a metal ion or an onium cation, m represents an integer of 1 to 3, and n represents an integer of 1 to 8.)

6. A polymer comprising a repeating unit represented by the following general formula (1) and a repeating unit having a fluorine atom (provided that said repeating unit represented by the general formula (1) is excluded), and having an acid dissociable group in the side chain. 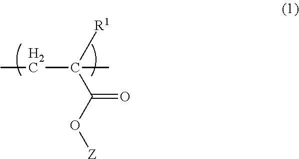
(In the general formula (1), R¹ represents a hydrogen atom, a methyl group, or a trifluoromethyl group, and Z represents a group having a structure which generates an acid when exposed to radiation.)

7. The polymer according to claim 6, further comprising at least one repeating unit selected from the group consisting of a repeating unit represented by the following general formula (2), a repeating unit represented by the following general formula (3), and a repeating unit represented by the following general formula (4). 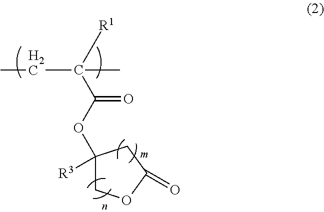
(In the general formula (2), R² represents a hydrogen atom, a methyl group, or a trifluoromethyl group, R³ represents a linear or branched alkyl group having 1 to 4 carbon atoms, m represents an integer of 1 to 3, and n represents an integer of 1 to 3.) 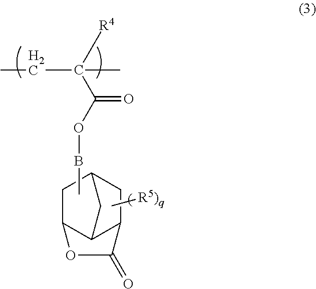
(In the general formula (3), R⁴ represents a hydrogen atom, a methyl group, or a trifluoromethyl group, R⁵ represents a hydrogen atom, a linear or branched alkyl group having 1 to 4 carbon atoms, a linear or branched fluorinated alkyl group having 1 to 4 carbon atoms, or a linear or branched alkoxyl group having 1 to 4 carbon atoms, q represents an integer of 0 to 3, B represents a single bond, an ether group, an ester group, a carbonyl group, a divalent chained hydrocarbon group having 1 to 30 carbon atoms, a divalent alicyclic hydrocarbon group having 3 to 30 carbon atoms, a divalent aromatic hydrocarbon group having 6 to 30 carbon atoms, or a divalent group obtained by combination thereof.) 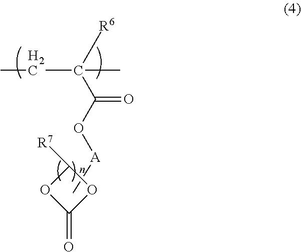
(In the general formula (4), R⁶ represents a hydrogen atom, a methyl group, or a trifluoromethyl group, R⁷ each independently represents a hydrogen atom, a chained hydrocarbon group having 1 to 5 carbon atoms, A represents a single bond, a divalent or trivalent chained hydrocarbon group having 1 to 30 carbon atoms, a divalent or trivalent alicyclic hydrocarbon group having 3 to 30 carbon atoms, or a divalent or trivalent aromatic hydrocarbon group having 6 to 30 carbon atoms; when A is trivalent, a carbon atom included in A and a carbon atom constituting the cyclic carbonic acid ester bind to each other thereby to form a ring structure, and n represents an integer of 2 to 4.)

8. A method for forming a resist pattern, comprising,
(1) forming a photoresist film on a substrate by using said radiation sensitive resin composition according to claim 1,
(2) subjecting said photoresist film to a liquid immersion exposure process, and
(3) developing the photoresist film obtained after said liquid immersion exposure process to form a resist pattern.
